(19) United States
(12) Patent Application Publication
(10) Pub. No.: US 2026/0007001 A1
(43) Pub. Date: Jan. 1, 2026

(54) DISPLAY PANEL AND ELECTRONIC DEVICE INCLUDING THE SAME

(71) Applicant: Samsung Display Co., Ltd., Yongin-Si (KR)

(72) Inventors: Hwanhee Jeong, Yongin-si (KR); Deokjung Kim, Yongin-si (KR); Wonil Lee, Yongin-si (KR)

(21) Appl. No.: 19/249,006

(22) Filed: Jun. 25, 2025

(30) Foreign Application Priority Data
Jun. 26, 2024 (KR) 10-2024-0083887
Dec. 18, 2024 (KR) 10-2024-0190441

(51) Int. Cl. H10K 59/122; H10K 59/38

(52) U.S. Cl. CPC H10K 59/122; H10K 59/38

(57) ABSTRACT

Provided are a display panel and an electronic device including the display panel, the display panel including a first display area having first light-emitting diodes, a second display area having second light-emitting diodes, a bank layer in the first and second display areas and including first bank openings defining first emission areas of the first light-emitting diodes, second bank openings defining second emission areas of the second light-emitting diodes, and third bank openings defining hole areas between the second emission areas, and a reflection preventive layer including color filters including openings above the hole areas, wherein the first display area includes a first sub-area in contact with the second display area and a second sub-area outside the first sub-area, and the first emission areas of the first sub-area differ from the first emission areas of the second sub-area with respect to at least one of shape and arrangement.

### CROSS-REFERENCE TO RELATED APPLICATIONS

This application is based on and claims priority, under 35 U.S.C. § 119, to Korean Patent Application No. 10-2024-0083887 filed on Jun. 26, 2024 and Korean Patent Application No. 10-2024-0190441 filed on Dec. 18, 2024 in the Korean Intellectual Property Office, the disclosures of which are incorporated by reference herein in their entirety.

### BACKGROUND

### 1. Field

One or more embodiments relate to a display panel and an electronic device including the same.

### 2. Description of the Related Art

Recently, usage of display panels has become increasingly diverse. In addition, display panels have become thinner and lighter, allowing an expansion in their range of use and application.

As the area occupied by a display area in display panels has increased, various functions connected to or associated with display panels have been added. As a method of adding various functions while expanding the display area, research has been steadily conducted on a display panel which has, inside the display area, an area to add various functions except image display.

### SUMMARY

One or more embodiments include a display panel that may have improved reliability and transmittance in an area where a component is arranged, and an electronic device including the display panel.

Additional aspects will be set forth in part in the description which follows and, in part, will be apparent from the description, or may be learned by practice of the presented embodiments of the disclosure.

According to one or more embodiments, a display panel includes a first display area having first light-emitting diodes and first pixel circuits connected to the first light-emitting diodes, a second display area having second light-emitting diodes and second pixel circuits connected to the second light-emitting diodes, the second display area being at least partially surrounded by the first display area, a bank layer in the first display area and the second display area, the bank layer including first bank openings defining first emission areas of the first light-emitting diodes, second bank openings defining second emission areas of the second light-emitting diodes, and third bank openings defining hole areas between the second emission areas, and a reflection preventive layer on the first light-emitting diodes and the second light-emitting diodes and including color filters having openings above the hole areas, wherein the first display area includes a first sub-area in contact with the second display area and a second sub-area outside the first sub-area, and the first emission areas of the first sub-area differ from the first emission areas of the second sub-area with respect to at least one of shape and arrangement.

According to an embodiment, at least some of the first emission areas of the first sub-area may be adjacent to at least some of the hole areas of the second display area.

According to an embodiment, in a plan view, the first emission areas of the first sub-area may have a same shape as the second emission areas of the second display area.

According to an embodiment, in a plan view, the first emission areas of the second sub-area may have oval shapes, and the second emission areas of the second display area and the first emission areas of the first sub-area may have circular shapes.

According to an embodiment, in a plan view, the second emission areas of the second display area may have circular shapes, and the first emission areas of the first display area may have oval shapes.

According to an embodiment, in a plan view, the hole areas may have oval shapes.

According to an embodiment, in a plan view, major axes of the first emission areas of the first sub-area may be oriented in a same direction, and the first emission areas of the second sub-area may include a first-axis emission area and a second-axis emission area having major axes that are oriented in different directions.

According to an embodiment, in a plan view, at least some of the first emission areas of the first sub-area may be adjacent, in a first direction, to at least some of the hole areas of the second display area, and major axes of the first emission areas of the first sub-area may extend in a second direction perpendicular to the first direction.

According to an embodiment, the color filters of the reflection preventive layer may include a first color filter transmitting first color light, a second color filter transmitting second color light, and a third color filter transmitting third color light, and the first color filter, the second color filter, and the third color filter may define a light-blocking portion by overlapping one another.

According to an embodiment, the first color filter, the second color filter, and the third color filter may be sequentially arranged, and the first color filter, the second color filter, and the third color filter may respectively include first openings above the first emission areas, second openings above the second emission areas, and third openings above the hole areas.

According to an embodiment, a portion of the first color filter arranged between a first opening of the first openings and a third opening of the third openings in the first color filter may be covered by at least one of the second color filter and the third color filter.

According to one or more embodiments, an electronic device includes a display panel and a cover coupled to the display panel and having an opening exposing a portion of the display panel, wherein the display panel includes a first display area having first light-emitting diodes and first pixel circuits connected to the first light-emitting diodes, a second display area having second light-emitting diodes and second pixel circuits connected to the second light-emitting diodes, the second display area being at least partially surrounded by the first display area, a bank layer in the first display area and the second display area, the bank layer including first bank openings defining first emission areas of the first light-emitting diodes, respectively, second bank openings defining second emission areas of the second light-emitting diodes, respectively, and third bank openings defining hole areas between the second emission areas, and a reflection preventive layer on the first light-emitting diodes and the second light-emitting diodes and including color filters having openings above the hole areas, wherein the first display area includes a first sub-area in contact with the second display area and a second sub-area outside the first sub-area, and the first emission areas of the first sub-area differ from the first emission areas of the second sub-area with respect to at least one of shape and arrangement.

According to an embodiment, at least some of the first emission areas of the first sub-area may be adjacent to at least some of the hole areas of the second display area.

According to an embodiment, in a plan view, the first emission areas of the first sub-area may have a same shape as the second emission areas of the second display area.

According to an embodiment, in a plan view, the first emission areas of the second sub-area may have oval shapes, and the second emission areas of the second display area and the first emission areas of the first sub-area may have circular shapes.

According to an embodiment, in a plan view, the second emission areas of the second display area may have circular shapes, and the first emission areas of the first display area may have oval shapes.

According to an embodiment, in a plan view, major axes of the first emission areas of the first sub-area may be oriented in a same direction, and the first emission areas of the second sub-area may include a first-axis emission area and a second-axis emission area having major axes that are oriented in different directions.

According to an embodiment, in a plan view, at least some of the first emission areas of the first sub-area may be adjacent, in a first direction, to at least some of the hole areas of the second display area, and major axes of the first emission areas of the first sub-area may extend in a second direction perpendicular to the first direction.

According to an embodiment, the color filters of the reflection preventive layer may include a first color filter transmitting first color light, a second color filter transmitting second color light, and a third color filter transmitting third color light, and the first color filter, the second color filter, and the third color filter may define a light-blocking portion by overlapping one another.

The electronic device may further include a component arranged between the display panel and the cover, wherein the component may align with the hole area.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of an electronic device according to an embodiment;

FIG. 2A is a schematic exploded perspective view of the electronic device of FIG. 1;

FIG. 2B is a schematic block diagram of the electronic device of FIG. 1;

FIGS. 3A and 3B are each a schematic plan view of an electronic device according to an embodiment;

FIGS. 4A and 4B are each a schematic cross-sectional view of a portion of an electronic device according to an embodiment;

FIG. 5 is a schematic plan view of a display panel included in an electronic device according to an embodiment;

FIG. 6 is a schematic plan view of an arrangement of pixels of a first display area of a display panel according to an embodiment;

FIG. 7 is a schematic plan view of an arrangement of pixels of a second display area of a display panel according to an embodiment;

FIG. 8 is a schematic cross-sectional view of a first display area of a display panel according to an embodiment;

FIG. 9 is a schematic cross-sectional view of a second display area of a display panel according to an embodiment;

FIG. 10 is a schematic plan view of a display layer of a first display area of a display panel according to an embodiment;

FIG. 11 is a schematic plan view of a reflection preventive layer of a first display area of a display panel according to an embodiment;

FIG. 12 is a schematic plan view of a display layer of a second display area of a display panel according to an embodiment;

FIG. 13 is a schematic plan view of a reflection preventive layer of a second display area of a display panel according to an embodiment;

FIG. 14 is a schematic plan view of a portion of a display panel, the portion corresponding to region D of FIG. 5, according to an embodiment;

FIG. 15 is a schematic cross-sectional view of a portion of a display panel, the portion being taken along line A-A′ of FIG. 14, according to an embodiment;

FIG. 16 is a schematic plan view of a portion of a display panel according to a comparative embodiment;

FIG. 17 is a schematic cross-sectional view of a portion of a display panel, the portion being taken along line B-B′ of FIG. 16, according to a comparative embodiment;

FIG. 18 is a schematic plan view of a portion of a display panel according to an embodiment; and

FIG. 19 is a schematic cross-sectional view of a portion of a display panel, the portion being taken along line C-C′ of FIG. 18, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

While the disclosure is capable of having various modifications and alternative forms, embodiments thereof are shown by way of example in the drawings and will herein be described in detail. The effects and characteristics of the disclosure and methods of achieving the same will become apparent by referring to the embodiments described below in detail with reference to the drawings. However, the disclosure is not limited to the embodiments disclosed hereinafter and may be realized in various forms.

Hereinafter, embodiments will be described in detail by referring to the accompanying drawings wherein, when describing the accompanying drawings, elements that are the same as or corresponding to each other will be assigned the same reference numerals, repeated descriptions thereof will not be given.

In the embodiments described hereinafter, the terms “first,” “second,” etc. are used to distinguish an element from another and are not used to convey a specific order or priority in a restrictive sense.

As used herein, the singular expressions are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or element is referred to as being formed “on” another layer, area, or element, it can be directly or indirectly formed on the other layer, region, or element. That is, for example, intervening layers, regions, or elements may be present.

Also, for convenience of explanation, elements in the drawings may have exaggerated or reduced sizes. For example, sizes and thicknesses of the elements in the drawings are randomly indicated for convenience of explanation, and thus, the disclosure is not necessarily limited to the illustrations of the drawings.

When a certain embodiment may be implemented differently, a specific process order may be performed differently from the described order. For example, two consecutively described processes may be performed substantially at the same time or performed in an order opposite to the described order.

In this specification, the expression “A and/or B” may indicate A, B, or A and B. Also, the expression “at least one of A or B” may indicate A, B, or A and B.

In the embodiments hereinafter, it will be understood that when an element, an area, or a layer is referred to as being connected to another element, area, or layer, it can be directly and/or indirectly connected to the other element, area, or layer. For example, it will be understood in this specification that when an element, an area, or a layer is referred to as being in contact with or being electrically connected to another element, area, or layer, it can be directly and/or indirectly in contact with or electrically connected to the other element, area, or layer.

An x-axis, a y-axis and a z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

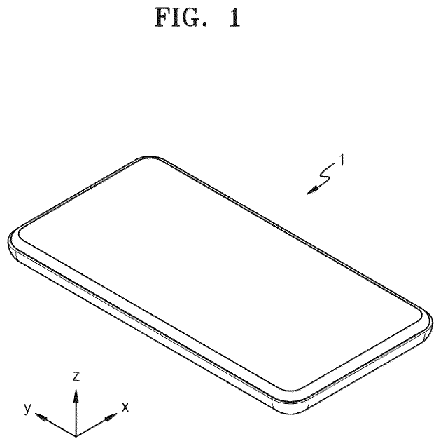

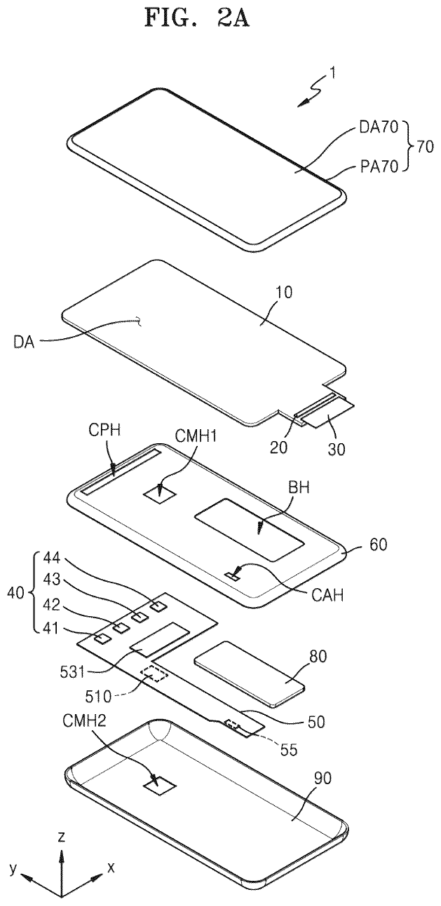

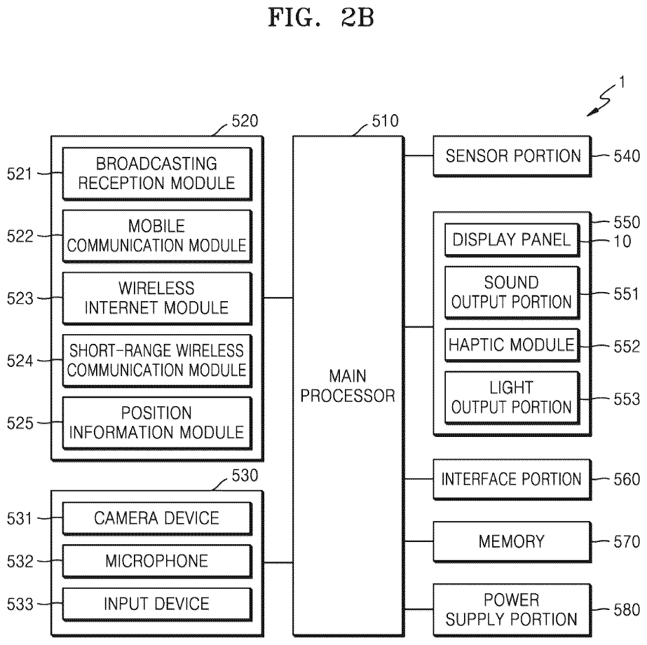

FIG. 1 is a schematic perspective view of the electronic device 1 according to an embodiment, FIG. 2A is a schematic exploded perspective view of the electronic device 1 of FIG. 1, and FIG. 2B is a schematic block diagram of the electronic device 1 of FIG. 1.

Referring to FIGS. 1 and 2A, the electronic device 1 according to an embodiment may display a motion image or a static image and may include portable electronic devices, such as a mobile phone, a smartphone, a tablet personal computer (PC), a mobile communication terminal, an electronic notebook, an electronic book, a portable multimedia player (PMP), a navigation device, or an ultra-mobile PC (UMPC), and may include various products, such as a television (TV), a notebook computer, a monitor, a signboard, or the Internet of things (IoT) device. Alternatively, the electronic device 1 according to an embodiment may include wearable devices, such as a smart watch, a watch phone, a glasses-type display, or a head-mounted display (HMD). Alternatively, the electronic device 1 according to an embodiment may include a gauge of a vehicle, a center information display (CID) on a center fascia or a dashboard of a vehicle, a room mirror display substituting a side-view mirror of a vehicle, or a display arranged on a rear surface of a front seat as an entertainment device for a backseat of a vehicle.

For convenience of explanation, FIGS. 1 and 2A illustrate that the electronic device 1 according to an embodiment includes a smartphone. The electronic device 1 may include a cover window 70, a display panel 10, a data driver 20, a display circuit board 30, components 40, a bracket 60, a main circuit board 50, a battery 80, and/or a lower cover 90.

In a plan view of this specification, “upper,” “lower,” “right,” and “left” positions indicate positions of the display panel 10 viewed in a direction perpendicular to the display panel 10. For example, the “upper” position may indicate a +y direction, the “lower” position may indicate a −y direction, the “right” position may indicate a +x direction, and the “left” position may indicate a −x direction.

In a plan view, the electronic device 1 may have an approximately rectangular shape. For example, as illustrated in FIG. 1, the electronic device 1 may have an approximately rectangular shape having a short side in an x-axis direction and a long side in a y-axis direction on an xy plane. Here, an edge at which the short side in the x-axis direction meets the long side in the y-axis direction may form a right angle or may have a circular shape having a certain curvature. However, in plan view, the electronic device 1 may have polygonal shapes other than the rectangular shape or may have an oval shape or an irregular shape.

The cover window 70 may be arranged above the display panel 10 to cover an upper surface of the display panel 10. The cover window 70 may perform the function of protecting the upper surface of the display panel 10.

The cover window 70 may include a transmissive cover portion DA70 that overlaps the display panel 10 when assembled and a light-blocking cover portion PA70 surrounding the transmissive cover portion DA70. The light-blocking cover portion PA70 may include a non-transparent material (for example, a colored non-transparent material) blocking light. The light-blocking cover portion PA70 may include a pattern which may be shown to a user when an image is not displayed.

The display panel 10 may be arranged below the cover window 70. The display panel 10 may overlap the transmissive cover portion DA70 of the cover window 70. The display panel 10 may include a display area DA. The display area DA may be where an image is displayed and may include an area (hereinafter, a component area) transmitting light emitted from the components 40 arranged below the display panel 10. The components 40 may include a sensor using visible rays, infrared rays, sound, etc. and a camera.

The display panel 10 may include a light-emitting display panel including a light-emitting diode. The light-emitting diode may include an organic light-emitting diode including an organic emission layer or an inorganic light-emitting diode including an inorganic material. When the light-emitting diode includes an inorganic light-emitting diode, the inorganic light-emitting diode may include a PN junction diode including inorganic semiconductor-based materials. When a voltage is applied to the PN junction diode in a normal direction, holes and electrons may be injected into the PN junction diode and energy generated by recombination of the holes and the electrons may be converted into light energy, and thus, light of a certain color may be emitted. The inorganic light-emitting diode may have a width of about several micrometers to about hundreds of micrometers. The inorganic light-emitting diode may be referred to as a micro light-emitting diode.

The display panel 10 may include a rigid display panel that is rigid and is not easily bent or a flexible display panel that is flexible and is easily bent, folded, or rolled. For example, the display panel 10 may include a foldable display panel which may be folded and unfolded, a curved display panel having a curved display surface, a bent display panel including bent portions excluding a display surface, a rollable display panel which may be rolled or unrolled, or a stretchable display panel which may be stretched.

The display panel 10 may include a transparent display panel, which is realized to be transparent so that an object or a background arranged on a lower surface of the display panel 10 may be seen on an upper surface of the display panel 10. Alternatively, the display panel 10 may include a reflective display panel configured to reflect an object or a background on the upper surface of the display panel 10.

The data driver 20 may be mounted on the display panel 10 as an integrated circuit (IC). However, the disclosure is not limited thereto. For example, the data driver 20 may be mounted on the display circuit board 30.

The display circuit board 30 may be attached to one side of the display panel 10. The display circuit board 30 may include a flexible printed circuit board (FPCB) which is bendable, a rigid printed circuit board (RPCB) which is rigid and not easily bent, or a complex printed circuit board including both of an FPCB and an RPCB. A touch sensor driver may be mounted on the display circuit board 30. The touch sensor driver may be formed as an IC. The touch sensor driver may be electrically connected to touch electrodes of an input sensing layer of the display panel 10 through the display circuit board 30.

The input sensing layer of the display panel 10 may sense a user's touch input by using at least one of various touch methods, such as a resistive layer method, a capacitance method, etc. When the input sensing layer of the display panel 10 senses a user's touch input through a capacitance method, the touch sensor driver may determine whether or not there is a user's touch input by applying driving signals to certain driving electrodes among the touch electrodes and may sense, through sensing electrodes from among the touch electrodes, voltages charged to mutual capacitances (hereinafter, referred to as “mutual capacities”) between the driving electrodes and the sensing electrodes.

The user's touch input may include a contact touch and a proximity touch. The contact touch may indicate a direct contact of a finger of a user or an object, such as a pen, or the like, with the cover window 70 arranged on the input sensing layer. The proximity touch may indicate a state in which a finger of a user or an object, such as a pen, or the like, is positioned to be adjacent to but apart from the cover window 70, like hovering. The touch sensor driver may transmit sensor data to a main processor 510 according to the sensed voltages, and the main processor 510 may analyze the sensor data to calculate a touch coordinate in which the touch input has occurred.

A controller configured to supply driving voltages to drive pixels of the display panel 10, a gate driver, and/or the data driver 20 may be arranged on the display circuit board 30.

The bracket 60 configured to support the display panel 10 may be arranged below the display panel 10. The bracket 60 may include plastic, metal, or both plastic and metal. The bracket 60 may include a first camera hole CMH1 into which a camera device 531 is inserted, a battery hole BH in which the battery 80 is arranged, a cable hole CAH through which a cable connected to the display circuit board 30 passes, and a component hole CPH that aligns with the components 40 upon assembly. The component hole CPH may overlap the components 40 of the main circuit board 50 when viewed in a third direction (a z-axis direction). For reference, the display area DA of the display panel 10 may overlap the components 40 of the main circuit board 50 when viewed in the third direction (the z-axis direction). However, according to necessity, the bracket 60 may not include the component hole CPH.

The components 40 included in the electronic device 1 may include a first component 41, a second component 42, a third component 43, and a fourth component 44 overlapping the display panel 10. Each of the first to fourth components 41 to 44 may include at least one of a proximity sensor, an illumination sensor, an iris sensor, a face recognition sensor, and a camera (or an image sensor). The proximity sensor using infrared rays may sense an object located to be proximate to an upper surface of the electronic device 1, and the illumination sensor may sense the brightness of light incident onto the upper surface of the electronic device 1. Also, the iris sensor may capture an image of an iris of a human arranged on the upper surface of the electronic device 1, and the camera may obtain image data with respect to an object arranged on the upper surface of the electronic device 1. However, the components 40 are not limited to the proximity sensor, the illumination sensor, the iris sensor, the face recognition sensor, and/or the camera and may include other sensors.

The main circuit board 50 and the battery 80 may be arranged below the bracket 60. The main circuit board 50 may include a printed circuit board or an FPCB.

The main circuit board 50 may include the main processor 510, the camera device 531, a main connector 55, and the components 40. The main processor 510 may include an IC. Depending on the embodiment, the electronic device 1 may include not only the camera device 531 arranged on an upper surface of the main circuit board 50, but also a camera device arranged on a lower surface of the main circuit board 50. Each of the main processor 510 and the main connector 55 may be arranged on any one of the upper surface and the lower surface of the main circuit board 50. The main circuit board 50 may be electrically connected to the display circuit board 30 through the main connector 55, etc.

The main processor 510 may control all functions of the electronic device 1. For example, the main processor 510 may output digital video data to the data driver 20 through the display circuit board 30, so that the display panel 10 may display an image. The main processor 510 may receive sensor data from the touch sensor driver. The main processor 510 may determine whether or not there is a user's touch, according to the sensor data, and may perform an operation according to a direct touch or a proximity touch of a user. The main processor 510 may include an application processor, a central processing unit, or a system chip including an IC.

The camera device 531 may process an image frame, such as a static image or a motion image, obtained in a camera mode through an image sensor, and may output the processed image frame to the main processor 510. The camera device 531 may include at least one of a camera sensor (for example, a charge-coupled device (CCD) sensor, a complementary metal-oxide semiconductor (CMOS) sensor, or the like), a photo sensor (or an image sensor), and a laser sensor.

A cable passing through the cable hole CAH of the bracket 60 may be connected to the main connector 55, and through this cable, the main circuit board 50 may be electrically connected to the display circuit board 30.

The electronic device 1 may be as illustrated in the block diagram of FIG. 2B. As illustrated, the electronic device 1 may include, in addition to the main processor 510, a wireless communicator 520, an input portion 530, a sensor portion 540, an output portion 550, an interface portion 560, a memory 570, and/or a power supply portion 580, illustrated in FIG. 2B.

The wireless communicator 520 may include at least one of a broadcasting reception module 521, a mobile communication module 522, a wireless Internet module 523, a short-range wireless communication module 524, and a position information module 525.

The broadcasting reception module 521 may receive, from an external broadcasting management server, a broadcasting signal and/or broadcasting-related information, through a broadcasting channel. The broadcasting channel may include a satellite channel or a ground wave channel.

The mobile communication module 522 may transmit and receive a wireless signal to and from at least one of a base station, an external terminal, and a server on mobile communication networks established according to the technical standards for mobile communication or the communication methods (for example, a global system for mobile communication (GSM), code division multiple access (CDMA), CDMA 2000, enhanced voice-data optimized or enhanced voice-data only (EV-DO), wideband CDMA (WCDMA), high speed downlink packet access (HSDPA), high speed uplink packet access (HSUPA), long term evolution (LTE), LTE-advanced (LTE-A), etc.). The wireless signal may include a sound call signal, a video telephony call signal, or various forms of data according to transmission and reception of text/multimedia messages.

The wireless Internet module 523 may indicate a module for wireless Internet access. The wireless Internet module 523 may be configured to transmit and receive a wireless signal on a communication network according to the wireless Internet techniques. The wireless Internet techniques may include, for example, a wireless local area network (WLAN), wireless-fidelity (Wi-Fi), Wi-Fi direct, and/or a digital living network alliance (DLNA).

The short-range wireless communication module 524 may be used for short-range communication and may support short-range communication by using at least one of Bluetooth™, radio frequency identification (RFID), infrared data association (IrDA), an ultra wideband (UWB), Zigbee, near-field communication (NFC), Wi-Fi, Wi-Fi direct, and a wireless universal serial bus (USB). The short-range wireless communication module 524 may support wireless communication between the electronic device 1 and a wireless communication system, between the electronic device 1 and another electronic device, or between the electronic device 1 and a network on which another electronic device (or an external server) is located, through a short-range wireless communication network. The short-range wireless communication network may include wireless personal area networks. The other electronic device may include a wearable device which may exchange data (or which may be synchronized) with the electronic device 1.

The position information module 525 may be configured to obtain a position of the electronic device 1, and may include a global positioning system (GPS) module or a Wi-Fi module.

The input portion 530 may include an image input portion such as the camera device 531 configured to input an image signal, a sound input portion such as a microphone 532 configured to input a sound signal, and an input device 533 configured to receive information from a user. The camera device 531 may process an image frame, such as a static image or a motion image, obtained through the image sensor in a video call mode or a photographing mode. The processed image frame may be displayed on the display panel 10 or stored in the memory 570. The microphone 532 may process an external sound signal into electrical sound data. The processed sound data may be variously used according to a function performed (or an application executed) by the electronic device 1.

The main processor 510 may control operations of the electronic device 1 according to information input through the input device 533. The input device 533 may include a mechanical input device, such as a button, a dome switch, a jog wheel, a jog switch, etc. on a rear surface or a side surface of the electronic device 1, or a touch input device. The touch input device may be formed as the input sensing layer of the display panel 10.

The sensor portion 540 may include one or more sensors configured to sense at least one of information in the electronic device 1, information of an ambient environment around the electronic device 1, and user information and generate a sensing signal according to the sensed information. Based on the sensing signal, the main processor 510 may drive the electronic device 1, control operations of the electronic device 1, or process data and perform functions or operations related to an application installed on the electronic device 1. The sensor portion 540 may include a proximity sensor, an illumination sensor, or a face recognition sensor as described above with respect to the components 40. However, the sensor portion 540 may include an acceleration sensor, a magnetic sensor, a gravity sensor (a G-sensor), a gyroscope sensor, a motion sensor, an RGB sensor, an infrared (IR) sensor, a finger scan sensor, an ultrasonic sensor, an optical sensor, and/or a battery gauge. In addition, the sensor portion 540 may include an environmental sensor or a chemical sensor. The environmental sensor may include, for example, a barometer, a hygrometer, a thermometer, a radiation detector sensor, a thermal detector sensor, and/or a gas detector sensor. The chemical sensor may include, for example, an electronic nose, a health case sensor, and/or a biometric sensor.

The output portion 550 may be configured to generate an output related to a visual sense, an auditory sense, a haptic sense, or the like and may include at least one of the display panel 10, a sound output portion 551, a haptic module 552, and a light output portion 553.

The display panel 10 may display (output) information processed by the electronic device 1. For example, the display panel 10 may display execution screen information of an application driven by the electronic device 1 or user interface (UI) or graphics UI (GUI) information according to the execution screen information. The display panel 10 may include a display layer for displaying an image and an input sensing layer for sensing a touch input of a user. Thus, while the display panel 10 may function as an example of the input device 533 configured to provide an input interface between the electronic device 1 and a user, the display panel 10 may function as an example of the output portion 550, configured to provide an output interface between the electronic device 1 and the user.

The sound output portion 551 may output sound data received from the wireless communicator 520 or stored in the memory 570 in a call signal reception mode, a call mode, a recording mode, a voice recognition mode, and/or a broadcasting reception mode. The sound output portion 551 may output a sound signal related to a function (for example, a call signal reception sound, a message reception sound, etc.) performed by the electronic device 1. The sound output portion 551 may include a receiver and a speaker. At least one of the receiver and the speaker may include a sound generation device which is attached below the display panel 10 and vibrates the display panel 10 to output sound. The sound generation device may include a piezoelectric element or a piezoelectric actuator contracting or expanding according to an electrical signal or an exciter vibrating the display panel 10 by generating a magnetic force by using a voice coil.

The haptic module 552 may generate various haptic effects which may be felt by a user. The haptic module 552 may provide vibration to the user as a haptic effect. The haptic module 552 may transmit the haptic effects through direct contact. Also, the haptic module may be configured to allow a user to feel the haptic effects through sensation of muscles such as a finger, an arm, etc.

The light output portion 553 may use light of a light source to output a signal for notifying an occurrence of an event. Examples of the event occurring in the electronic device 1 may include message reception, call signal reception, an absent call, alarm, schedule notification, email reception, and/or information reception through an application. The signal output by the light output portion 553 may be realized via emission of light of a single color or a plurality of colors on a front surface or a rear surface of the electronic device 1. The outputting of the signal may terminate via sensing of the electronic device 1 with respect to user's identification of an event.

The interface portion 560 may serve as a path between the electronic device 1 and various types of external devices connected to the electronic device 1. The interface portion 560 may include at least one of a wired/wireless headset port, an external charger port, a wired/wireless data port, a memory card port, a port connecting a device including an identification module, an audio input/output (I/O) port, a video I/O port, and an earphone port. When an external device is connected to the interface portion 560, the electronic device 1 may perform an appropriate control operation related to the external device connected to the interface portion 560.

The memory 570 may store data supporting various functions of the electronic device 1. The memory 570 may store a plurality of applications driven in the electronic device 1 and data and/or instructions for operations of the electronic device 1. At least some of the plurality of applications may be downloaded from an external server through wireless communication. The memory 570 may store an application for an operation of the main processor 510 and may temporarily store input/output data, for example, data such as a phone book, a message, a static image, and/or a motion image. Also, the memory 570 may store haptic data for vibration of various patterns provided to the haptic module 552 and sound data related to various sounds provided to the sound output portion 551.

The memory 570 may include a storage medium of at least one type from among a flash memory type, a hard disk type, a solid state disk (SSD) type, a silicon disk driver (SDD) type, a multimedia card micro type, a card type memory (for example, a secure digital (SD) or extreme digital (XD) memory, etc.) random-access memory (RAM), static RAM (SRAM), read-only memory (ROM), electrically erasable programmable ROM (EEPROM), programmable ROM (PROM), a magnetic memory, a magnetic disk, and an optical disk.

The power supply portion 580 may supply power to each component included in the electronic device 1 by receiving external power and/or internal power under control by the main processor 510. The power supply portion 580 may include the battery 80. Also, the power supply portion 580 may include a connection port, and the connection port may be an example of the interface portion 560, to which an external charger supplying power for charging the battery is electrically connected. Alternatively, the power supply portion 580 may be configured to charge the battery 80 in a wireless fashion. The battery 80 may be arranged not to overlap the main circuit board 50 in the third direction (the z direction). The battery 80 may overlap the battery hole BH of the bracket 60.

The lower cover 90 may form the exterior of the electronic device 1 and may have an opening exposing a portion of the display panel 10. The lower cover 90 may be shaped such that a surface of the lower cover 90, the surface that overlaps the display panel 10, may be open, and may be fastened to the display panel 10. The lower cover 90 may be located at the opposite side to the cover window 70 with the display panel 10 therebetween. The lower cover 90 may be arranged below the main circuit board 50 and the battery 80. The lower cover 90 may be fastened to the bracket 60 and fixed. The lower cover 90 may form the exterior of a lower surface of the electronic device 1. The lower cover 90 may include plastic, metal, or both plastic and metal.

A second camera hole CMH2 exposing a lower surface of the camera device 531 may be formed in the lower cover 90. The position of the camera device 531 and the positions of the first camera hole CMH1 and the second camera hole CMH2 that align with the camera device 531 upon assembly are not limited to the positions illustrated in FIG. 2A and may be variously modified.

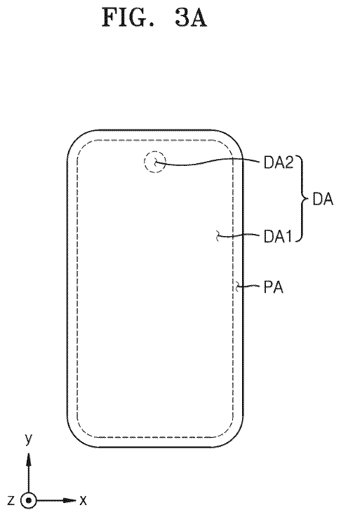

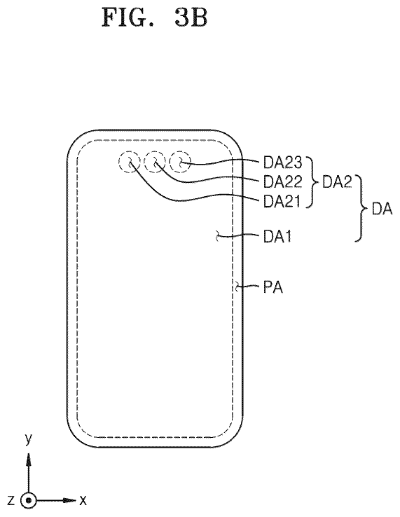

FIGS. 3A and 3B are each a schematic plan view of the electronic device 1 according to an embodiment.

The electronic device 1 may include a display area DA displaying an image and a peripheral area PA outside the display area DA. In a plan view, the display area DA may have a rectangular shape as illustrated in FIG. 1. According to another embodiment, the display area DA may have a polygonal shape, such as a triangular shape, a pentagonal shape, a hexagonal shape, etc., a circular shape, an oval shape, an amorphous shape, etc. The display area DA may have a round corner. The peripheral area PA may be a type of non-display area in which display elements are not arranged. The display area DA may be entirely surrounded by the peripheral area PA.

In the display area DA, pixels including various display elements such as an organic light-emitting diode may be arranged. The pixels may include a plurality of pixels.

The plurality of pixels may be arranged in various shapes in an x direction and a y direction, for example, as a stripe arrangement, a pentile arrangement, or a mosaic arrangement, and may display an image.

The display area DA may include a first display area DA1 and a second display area DA2. At least a portion of the display area DA may be configured as the second display area DA2. As illustrated in FIG. 1, only a portion of the display area DA may be configured as the second display area DA2. According to another embodiment, the entire display area DA may be configured as the second display area DA2.

The second display area DA2 may be where the components 40 (see FIG. 2A) for adding various functions to the electronic device 1 are arranged and may be referred to as a component area.

FIG. 3A illustrates that only one second display area DA2 is located in the display area DA. However, the disclosure is not necessarily limited thereto. According to another embodiment, as illustrated in FIG. 3B, the electronic device 1 may include two or more second display areas DA2. The shapes and sizes of the plurality of second display areas DA2 may be the same as each other or different from each other.

When viewed in a direction approximately perpendicular to an upper surface of the electronic device 1, the second display area DA2 may have various shapes, such as a circular shape, an oval shape, a polygonal shape such as a quadrangular shape, a star shape, or a diamond shape. The components 40 having different functions may be arranged to correspond to the plurality of second display areas DA2, respectively. For example, a camera may be arranged in a second-1 display area DA21, an illumination sensor may be arranged in a second-2 display area DA22, and a proximity sensor may be arranged in a second-3 display area DA23.

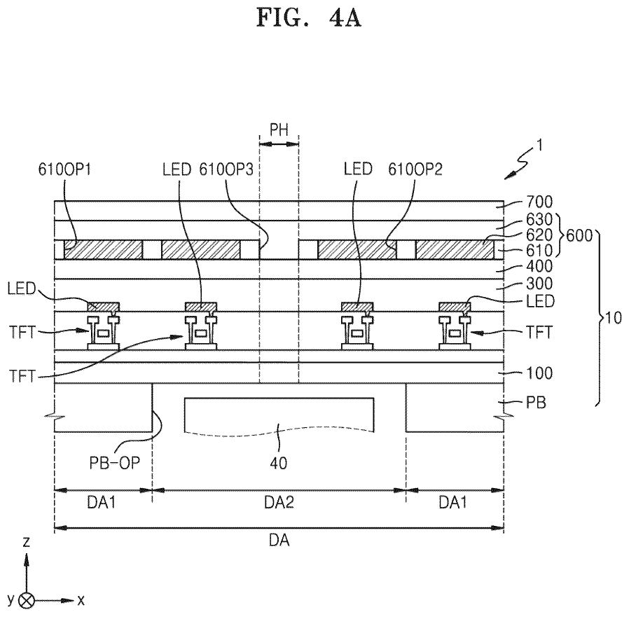

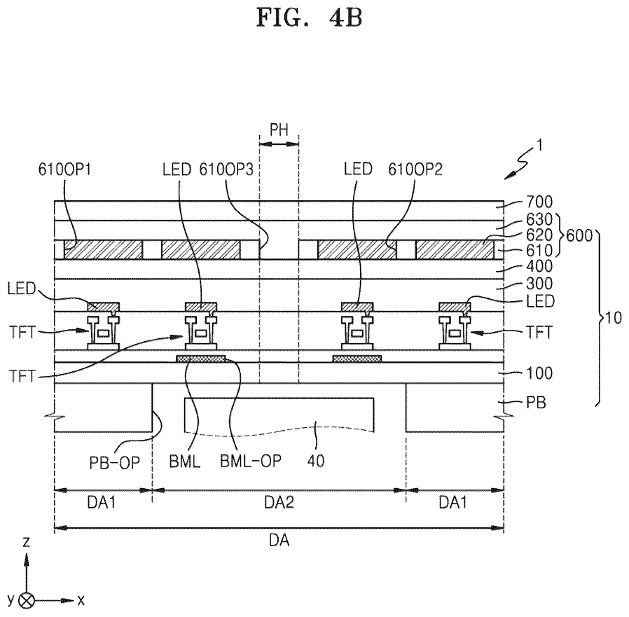

FIGS. 4A and 4B are schematic cross-sectional views of a portion of the electronic device 1 according to an embodiment.

The electronic device 1 may include the display panel 10 and the components 40 on the display panel 10.

The display panel 10 may include the display area DA, and the display area DA may include a first display area DA1 occupying the most of the display area DA and a second display area DA2 having a relatively smaller area than the first display area DA1.

The display panel 10 may include a substrate 100, a display layer on the substrate 100, and a thin-film encapsulation layer 300, an input sensing layer 400, a reflection preventive layer 600, and a window 700 on the display layer. The display layer may include a thin-film transistor TFT on the substrate 100 and a display element (for example, a light-emitting diode LED) electrically connected to the thin-film transistor TFT. The thin-film encapsulation layer 300 may cover a display element of the display layer.

The substrate 100 may include glass or polymer resins. The substrate 100 including the polymer resins may be flexible, foldable, rollable, or bendable. The substrate 100 may have a multi-layered structure including a layer including the polymer resins described above and an inorganic layer (not shown).

A lower protective film PB may be arranged on a lower surface of the substrate 100. The lower protective film PB may be attached to the lower surface of the substrate 100. An adhesive layer may be arranged between the lower protective film PB and the substrate 100. Alternatively, the lower protective film PB may be directly formed on the lower surface of the substrate 100, and in this case, the adhesive layer may not be arranged between the lower protective film PB and the substrate 100.

The lower protective film PB may support and protect the substrate 100. The lower protective film PB may have an opening PB-OP that aligns with the second display area DA2. The lower protective film PB may include an organic insulating material, such as polyethylene terephthalate (PET) or polyimide (PI). The area of the opening PB-OP provided in the lower protective film PB may not be wholly or partially aligned with the second display area DA2.

The thin-film transistor TFT and the light-emitting diode LED, which is a display element electrically connected to the thin-film transistor TFT, may be arranged on an upper surface of the substrate 100. The light-emitting diode LED may include an organic light-emitting diode including an organic material. The organic light-emitting diode may emit red, green, or blue light.

The light-emitting diode LED may include an inorganic light-emitting diode including an inorganic material. The inorganic light-emitting diode may include a PN junction diode including inorganic semiconductor-based materials. When a voltage is applied to the PN junction diode in a normal direction, holes and electrons may be injected into the PN junction diode and energy generated by recombination of the holes and the electrons may be converted into light energy, and thus, light of a certain color may be emitted. The inorganic light-emitting diode described above may have a width that is several to hundreds of micrometers or several to hundreds of nanometers. According to some embodiments, the light-emitting diode LED may include a quantum dot light-emitting diode. An emission layer of the light-emitting diode LED may include an organic material, an inorganic material, a quantum dot, an organic material and a quantum dot, or an inorganic material and a quantum dot.

The light-emitting diode LED may be electrically connected to the thin-film transistor TFT arranged therebelow. The thin-film transistor TFT and the light-emitting diode LED may be arranged in each of the first display area DA1 and the second display area DA2.

A hole area PH may be located in the second display area DA2 in which the components 40 are arranged. As illustrated in FIGS. 4A and 4B, the hole area PH may be arranged in the second display area DA2 between the light-emitting diodes LED adjacent to each other. The light-emitting diode LED, which is the display element, the thin-film transistor TFT and a line forming a pixel circuit, may not be arranged in the hole area PH.

The hole area PH may be a transmissive area transmitting light/signals emitted from the components 40 or light/signals toward the components 40. A transmittance of the hole area PH may be about at least 30%, about at least 40%, about at least 50%, about at least 60%, about at least 70%, about at least 75%, about at least 80%, about at least 85%, or about at least 90%.

The components 40 may include a sensor, such as a proximity sensor, an illumination sensor, an iris sensor, or a face recognition sensor, and a camera (or an image sensor). The components 40 may use light. For example, the components 40 may emit and/or receive light of bands of infrared light, ultraviolet light, and visible light. The proximity sensor using infrared rays may sense an object arranged to be proximate to an upper surface of the electronic device 1, and the illumination sensor may sense the brightness of light incident onto the upper surface of the electronic device 1. Also, the iris sensor may capture an image of an iris of a human arranged on the upper surface of the electronic device 1, and the camera may receive light with respect to an object arranged on the upper surface of the electronic device 1.

In order to prevent deterioration of the function of the thin-film transistor TFT due to light passing through the hole area PH, a light-blocking metal layer BML may be arranged between the substrate 100 and the thin-film transistor TFT. As illustrated in FIG. 4B, the light-blocking metal layer BML may be arranged in the second display area DA2. According to another embodiment, the light-blocking metal layer BML may also be arranged in the first display area DA1. The light-blocking metal layer BML may include an opening BML-OP overlapping the hole area PH.

The thin-film encapsulation layer 300 may cover the light-emitting diodes LED. The thin-film encapsulation layer 300 may include at least one inorganic encapsulation layer and at least one organic encapsulation layer.

The input sensing layer 400 may be formed on the thin-film encapsulation layer 300. The input sensing layer 400 may obtain coordinate information according to an external input, for example, a touch event of a finger or an object such as a stylus pen. The input sensing layer 400 may include a touch electrode and trace lines connected to the touch electrode. The input sensing layer 400 may sense the external input by using a mutual cap method or a self-cap method.

The reflection preventive layer 600 may reduce the reflectivity of light (external light) incident from the outside toward the display panel 10. According to an embodiment, the reflection preventive layer 600 may include a light-blocking layer 610, color filters 620, and an overcoat layer 630. The light-blocking layer 610 may include an opening 610OP1 overlapping the light-emitting diode LED in the first display area DA1 and an opening 610OP2 overlapping the light-emitting diode LED in the second display area DA2, and the color filters 620 may be arranged in the openings 610OP1 and 610OP2, respectively. The light-blocking layer 610 may include an opening 610OP3 overlapping the hole area PH. A portion of the overcoat layer 630 may at least partially fill the opening 610OP3 in the hole area PH. The overcoat layer 630 may include an organic material, such as resins, and the organic material may be transparent.

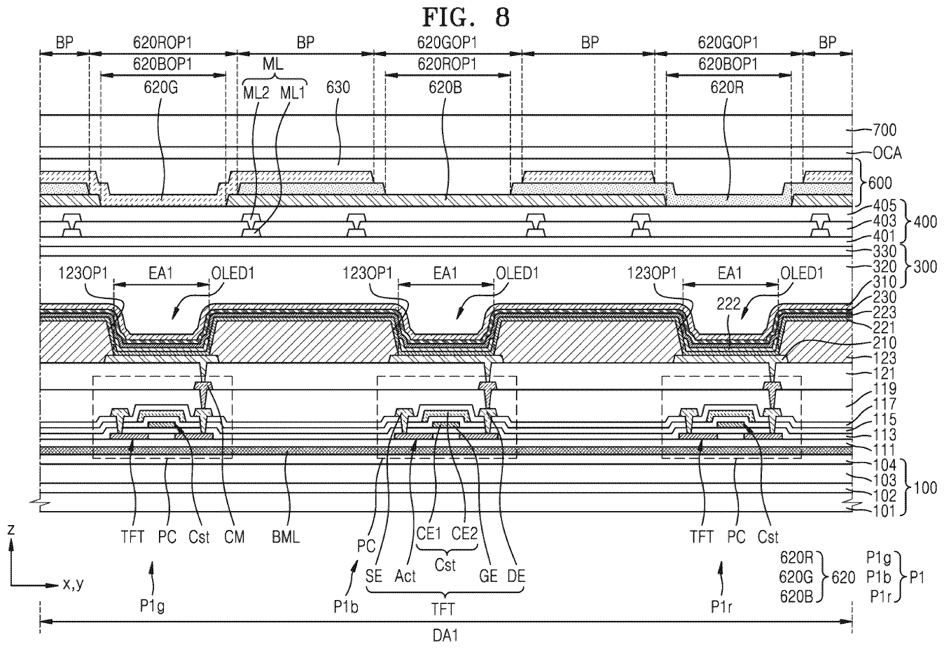

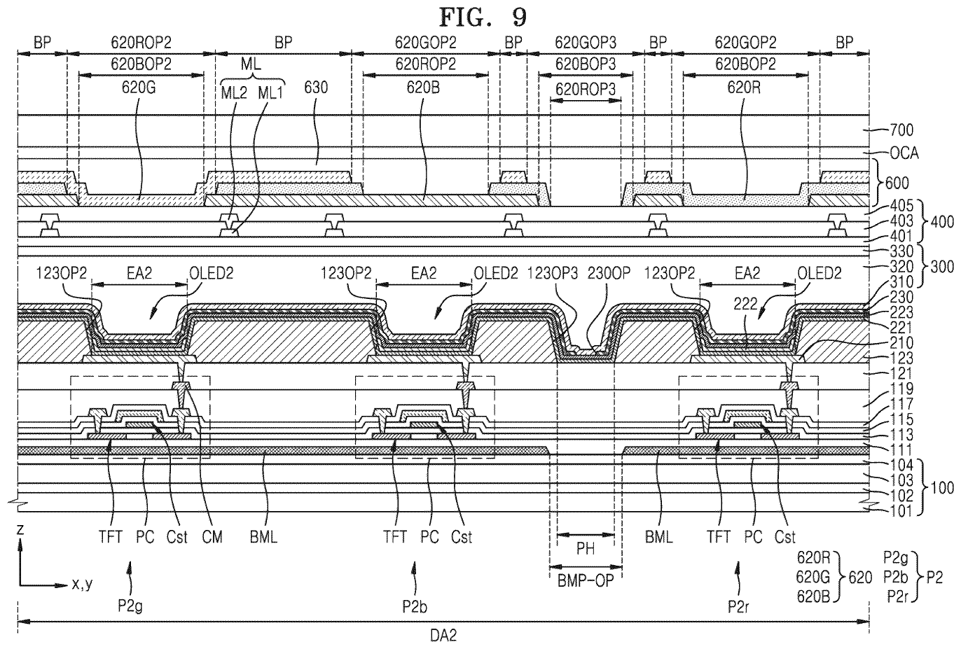

According to another embodiment, as illustrated in FIGS. 8 and 9 described below, the reflection preventive layer 600 may include the color filters 620 and the overcoat layer 630. The color filters 620 may overlap each other and may form a light-blocking portion BP. The color filters 620 may respectively include openings overlapping the hole area PH. A portion of the overcoat layer 630 may at least partially fill the openings in the hole area PH.

That is, the color filters 620 and/or the light-blocking layer 610 may not be arranged in a portion of the reflection preventive layer 600 that is in the hole area PH.

The window 700 may be arranged on the reflection preventive layer 600. The window 700 may be coupled to the reflection preventive layer 600 via an adhesive layer, such as an optically clear adhesive (OCA). The window 700 may include a glass material or a plastic material. The glass material may include ultra-thin glass. The plastic material may include polyether sulfone, polyacrylate, polyether imide, polyethylene naphthalate, polyethylene terephthalate, polyphenylene sulfide, polyarylate, polyimide, polycarbonate, cellulose acetate propionate, or the like.

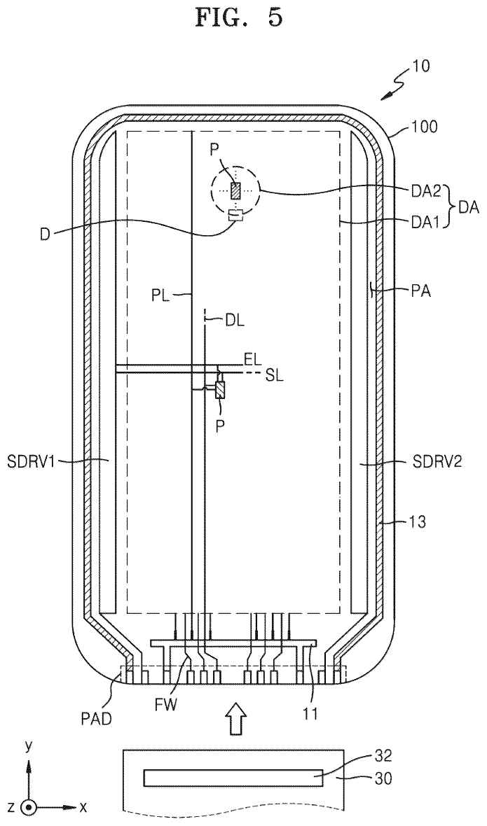

FIG. 5 is a schematic plan view of the display panel 10 included in the electronic device 1 according to an embodiment.

Referring to FIG. 5, various elements included in the display panel 10 may be arranged on the substrate 100. The substrate 100 may include the display area DA and the peripheral area PA surrounding the display area DA. The display area DA may include the first display area DA1 and the second display area DA2.

The plurality of pixels P may be arranged in the first display area DA1 and the second display area DA2. Each of the plurality of pixels P may be realized as a display element, such as an organic light-emitting diode OLED. Each pixel P may emit, for example, red, green, blue, or white light. According to an embodiment, the resolution of the second display area DA2 may be the same as the resolution of the first display area DA1. However, the disclosure is not limited thereto. According to another embodiment, the resolution of the second display area DA2 may be lower than the resolution of the first display area DA1.

Each of the pixel circuits configured to drive the pixels P may be electrically connected to outer circuits arranged in the peripheral area PA. A first scan driving circuit SDRV1, a second scan driving circuit SDRV2, a terminal portion PAD, a driving voltage supply line 11, and a common voltage supply line 13 may be arranged in the peripheral area PA.

The first scan driving circuit SDRV1 may be configured to apply, to each of the pixel circuits configured to drive the pixels P, a scan signal through a scan line SL. The first scan driving circuit SDRV1 may be configured to apply, to each pixel circuit, an emission control signal through an emission control line EL. The second scan driving circuit SDRV2 may be arranged across the display area DA from the first scan driving circuit SDRV1 and may extend approximately parallel to the first scan driving circuit SDRV1. Some of the pixel circuits of the pixels P in the display area DA may be electrically connected to the first scan driving circuit SDRV1, and the others may be electrically connected to the second scan driving circuit SDRV2. The second scan driving circuit SDRV2 may be omitted.

The terminal portion PAD may be arranged at a side of the substrate 100. The terminal portion PAD may not be covered by an insulating layer, and may be connected to the display circuit board 30. A display driver 32 may be arranged on the display circuit board 30.

The display driver 32 may be configured to generate a control signal transmitted to the first scan driving circuit SDRV1 and the second scan driving circuit SDRV2. The display driver 32 may be configured to generate a data signal, and the generated data signal may be transmitted to the pixel circuits of the pixels P through a fan-out line FW and a data line DL connected to the fan out line FW.

The display driver 32 may be configured to supply a driving voltage ELVDD to the driving voltage supply line 11 and supply a common voltage ELVSS to the common voltage supply line 13. The driving voltage ELVDD may be applied to the pixel circuits of the pixels P through a driving voltage line PL connected to the driving voltage supply line 11, and the common voltage ELVSS may be applied to an opposite electrode of the display element through the common voltage supply line 13.

The driving voltage supply line 11 may be connected the terminal portion PAD and may extend in an x direction at a lower portion of the display area DA. The common voltage supply line 13 may be connected to the terminal portion PAD and may have a loop shape having an open side to partially surround the display area DA.

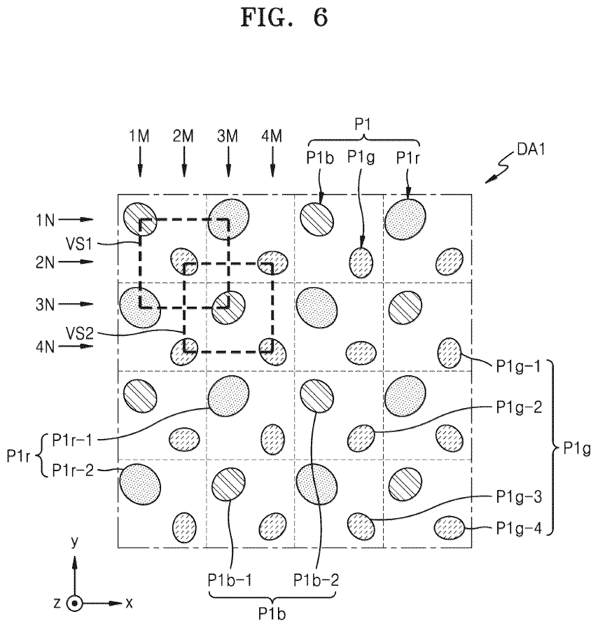

FIG. 6 is a schematic plan view of an arrangement of the pixels of the first display area DA1 of the display panel 10 according to an embodiment.

Referring to FIG. 6, first pixels P1 may be arranged in the first display area DA1. According to an embodiment, the first pixels P1 may include a red first pixel P1r, a green first pixel P1g, and a blue first pixel P1b.

The red first pixel P1r, the green first pixel P1g, and the blue first pixel P1b may have a repeated arrangement structure. According to an embodiment, the blue first pixel P1b and the red first pixel Pir may be alternately arranged in a first row 1N, the green first pixels P1g may be arranged in a second row 2N spaced apart from each other by a certain distance, the second row 2N being adjacent to the first row 1N, the blue first pixel Pib and the red first pixel P1r may be alternately arranged in a third row 3N adjacent to the second row 2N, and the green first pixels P1g may be arranged in a fourth row 4N spaced apart from each other by a certain distance, the fourth row 4N being adjacent to the third row 3N. Although the blue first pixel P1b and the red first pixel P1r are arranged in an alternating manner in each odd-numbered row, adjacent odd rows start with a different one of the blue and red first pixel P1b/P1r. Hence, in each odd-numbered column, the blue first pixel P1b and the red first pixel P1r are arranged in an alternating manner. The pixel arrangements in the first to fourth rows 1N to 4N described above may be repeated to the last row.

The positions of the blue first pixel P1g and the red first pixel P1r arranged in the first row 1N may be offset by a column in the x-direction with respect to the positions of the green first pixels P1g in the second row 2N. For example, the blue first pixel P1b and the red first pixel P1r may be alternately arranged in odd-numbered columns 1M, 3M, etc. while the green first pixels P1g may be arranged in even-numbered columns 2M, 4M, etc. This results in the blue first pixel P1b and the red first pixel P1r being in a staggered arrangement with respect to the green first pixels P1g. The pixel arrangements in the first to fourth columns 1M to 4M described above may repeat to the last column.

The red first pixel Pir and the blue first pixel P1b may be arranged at vertices of a virtual quadrangle VS1 having any one green first pixel P1g at its center. The red first pixel P1r may be arranged at each of the vertices diagonal to each other in the virtual quadrangle VS1, and the blue first pixel P1b may be arranged at each of the vertices diagonal to each other in the virtual quadrangle VS1. Also, the green first pixels P1g may be respectively arranged at vertices of a virtual quadrangle VS2 having the blue first pixel P1b or the red first pixel P1r at its center, the blue first pixel P1b and the red first pixel P1r being located at any one of the vertices of the virtual quadrangle VS1. According to an embodiment, the virtual quadrangles VS1 and VS2 may include rectangles. For example, the virtual quadrangles VS1 and VS2 may include squares.

Also, to express this pixel arrangement structure in different words, the red first pixel P1r, the green first pixel P1g, and the blue first pixel P1b may be arranged to have a pentile™ structure, for example, a diamond pentile structure. However, the disclosure is not necessarily limited thereto. According to another embodiment, the red first pixel P1r, the green first pixel P1g, and the blue first pixel P1b may be arranged to have a stripe structure.

According to an embodiment, the red first pixel P1r, the green first pixel P1g, and the blue first pixel P1b may have oval shapes. However, the disclosure is not limited thereto. According to another embodiment, the red first pixel P1r, the green first pixel P1g, and the blue first pixel P1b may have circular shapes or polygonal shapes. The polygonal shapes may include shapes having round vertices.

The sizes (or the widths) of the first red pixel P1r, the green first pixel P1g, and the blue first pixel P1b may be different from each other. For example, the green first pixel P1g may have a smaller size (width) than the red first pixel Pir and the blue first pixel P1b. The blue first pixel P1b may have a greater size (width) than the red first pixel P1r. According to another embodiment, the red first pixel P1r, the green first pixel P1g, and the blue first pixel P1b may have substantially the same sizes (or widths) as each other. Like this, various modifications are possible. The sizes may be measured in the direction of the longest axis of the pixel.

In this specification, a pixel may be a minimum unit to realize an image and may refer to an emission area of an organic light-emitting diode, which is a display element. An emission area of the pixel may be defined by a bank opening provided in a bank layer.

The width (or the size) of the pixel may denote the width (or the size) of the emission area of the organic light-emitting diode, and the width (or the size) of the emission area may be the same as the width (or the size) of the bank opening provided in the bank layer. Likewise, a planar shape of the pixel may denote a planar shape of the emission area of the organic light-emitting diode, and the planar shape of the emission area may substantially match a planar shape of the bank opening provided in the bank layer. Also, the pixel arrangement structure may be understood as an arrangement structure of the emission area.

According to an embodiment, at least some of the first pixels P1 arranged in the first display area DA1 of the display panel 10 may be provided to have oval shapes. Here, the first pixels P1 in the first display area DA1 may include the plurality of first pixels P1 having the oval shapes with axes extending in different directions, wherein the plurality of first pixels P1 may be irregularly or regularly arranged. In this case, a multi-phase phenomenon due to light reflected from each of the first pixels P1 may be reduced.

According to an embodiment, the green first pixels P1g may include the plurality of green first pixels P1g having oval shapes with axes extending in different directions. For example, the green first pixels P1g may include a first-axis green first pixel P1g-1, a second-axis green first pixel P1g-2, a third-axis green first pixel P1g-3, and a fourth-axis green first pixel P1g-4. The first-axis green first pixel P1g-1, the second-axis green first pixel P1g-2, the third-axis green first pixel P1g-3, and the fourth-axis green first pixel P1g-4 may have oval shapes. However, their axes, for example major axes, are oriented in different directions. For example, the major axis of the first-axis green first pixel P1g-1 may extend in a direction perpendicular to an x direction, and the major axis of the second-axis green first pixel P1g-2 may extend in a direction that is about 45° with respect to the x direction. The major axis of the third-axis green first pixel P1g-3 may extend in a direction that is about 135° (or)−45° with respect to the x direction, and the major axis of the fourth-axis green first pixel P1g-4 may extend in a direction parallel to the x direction. That is, the major axis of the first-axis green first pixel P1g-1 may extend in the direction perpendicular to the x direction. The major axis of the second-axis green first pixel P1g-2 may extend in an approximately +α direction with respect to the x direction, and the major axis of the third-axis green first pixel P1g-3 may extend in an approximately −α direction with respect to the x direction. The major axis of the fourth-axis green first pixel P1g-4 may extend in the direction parallel to the x direction. Here, a denotes an angle formed by the major axis of the green first pixel P1g with the x direction, which is an acute angle. For example, a may be 45°.

According to an embodiment, the first-axis green first pixels P1g-1 to the fourth-axis green first pixels P1g-4 may be arranged without a pattern or randomly. However, the disclosure is not limited thereto. According to another embodiment, orientations of the first-axis green first pixels P1g-1 to the fourth-axis green first pixels P1g-4 may be arranged regularly.

According to an embodiment, the red first pixels P1r may include the plurality of red first pixels P1r having oval shapes, axes of which are in different directions. For example, the red first pixels P1r may include a first-axis red first pixel P1r-1 and a second-axis red first pixel P1r-2. The first-axis red first pixel P1r-1 and the second-axis red first pixel P1r-2 may have oval shapes. However, their axes, for example major axes, are oriented in different directions. For example, the major axis of the first-axis red first pixel P1r-1 may extend in a direction that is about 45° with respect to the x direction, and the major axis of the second-axis red first pixel Pr-2 may extend in a direction that is about 135° (or)−45° with respect to the x direction. That is, the major axis of the first-axis red first pixel P1r-1 may extend in a +B direction with respect to the x direction, and the major axis of the second-axis red first pixel Pr-2 may extend in a −β direction with respect to the x direction. Here, B denotes an angle formed by the major axis of the red first pixel P1r with the x direction, which is an acute angle. For example, β may be 45°.

According to an embodiment, the first-axis red first pixels P1r-1 and the second-axis red first pixels P1r-2 may be regularly arranged. For example, as illustrated in FIG. 6, in the arrangement of the red first pixels P1r, the first-axis red first pixels P1r-1 and the second-axis red first pixels P1r-2 may be arranged in odd rows and odd columns. However, the disclosure is not necessarily limited thereto. According to another embodiment, the first-axis red first pixels P1r-1 and the second-axis red first pixels P1r-2 may be arranged in even rows and even columns, without a pattern, or randomly.

According to an embodiment, the blue first pixels P1b may include the plurality of blue first pixels P1b having oval shapes, axes of which are in different directions. For example, the blue first pixels P1b may include a first-axis blue first pixel P1b-1 and a second-axis blue first pixel P1b-2. The first-axis blue first pixel P1b-1 and the second-axis blue first pixel P1b-2 may have oval shapes. However, their axes, for example major axes, are oriented in different directions. For example, the major axis of the first-axis blue first pixel P1b-1 may extend in a direction that is 45° with respect to the x direction, and the major axis of the second-axis blue first pixel P1b-2 may extend in a direction that is 135° (or)−45° with respect to the x direction. That is, the major axis of the first-axis blue first pixel P1b-1 may extend in a +y direction with respect to the x direction, and the major axis of the second-axis blue first pixel P1b-2 may extend in a −y direction with respect to the x direction. Here, y denotes an angle formed by the major axis of the blue first pixel P1b with the x direction, which is an acute angle. For example, y may be 45°.

According to an embodiment, the first-axis blue first pixels P1b-1 and the second-axis blue first pixels P1b-2 may be regularly arranged. For example, as illustrated in FIG. 6, in the arrangement of the blue first pixels P1b, the first-axis blue first pixels P1b-1 and the second-axis blue first pixels P1b-2 may be arranged in odd rows and odd columns in a staggered manner. However, the disclosure is not necessarily limited thereto. According to another embodiment, the first-axis blue first pixels P1b-1 and the second-axis blue first pixels P1b-2 may be arranged in even rows and even columns, without a pattern, or randomly.

FIG. 6 illustrates the first-axis red first pixel P1r-1 and the second-axis red first pixel P1r-2 having two different major axial directions, the first-axis blue first pixel P1b-1 and the second-axis blue first pixel P1b-2 having two different major axial directions, and the first-axis green first pixel P1g-1 to the fourth-axis green first pixel P1g-4 having four different major axial directions. However, the disclosure is not necessarily limited thereto. According to another embodiment, the display panel 10 may include the green first pixels P1g having at least two and less than four different major axial directions, or more than four different major axial directions, the red first pixels P1r having at least three different major axial directions, and the blue first pixels P1b having at least three different major axial directions. According to another embodiment, at least one of the green first pixel P1g, the red first pixel P1r, and the blue first pixel P1b may not have an oval shape or may have an oval shape with matching axial orientation.

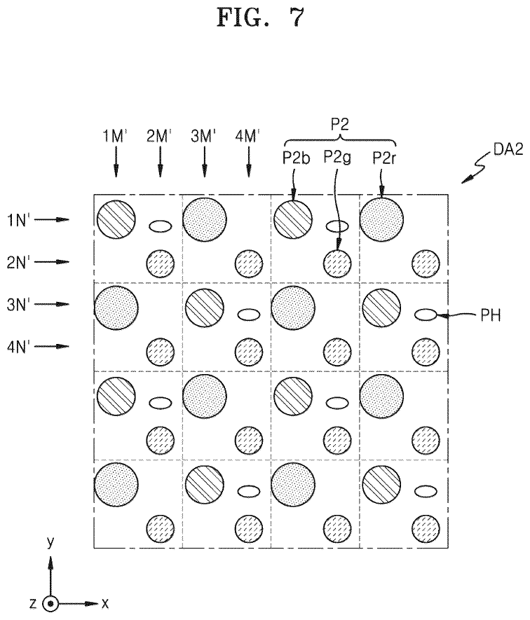

FIG. 7 is a schematic plan view of an arrangement of the pixels of the second display area DA2 of the display panel 10 according to an embodiment.

Referring to FIG. 7, second pixels P2 may be arranged in the second display area DA2. The second pixels P2 may include a red second pixel P2r, a green second pixel P2g, and a blue second pixel P2b.

The red second pixel P2r, the green second pixel P2g, and the blue second pixel P2b may have a repeated arrangement structure. According to an embodiment, the red second pixel P2r, the green second pixel P2g, and the blue second pixel P2b in the second display area DA2 may have the same pixel arrangement as the red first pixel P1r, the green first pixel P1g, and the blue first pixel P1b in the first display area DA1. For example, the red second pixel P2r, the green second pixel P2g, and the blue second pixel P2b may be arranged to have a pentile™ structure, for example, a diamond pentile structure.

However, the disclosure is not necessarily limited thereto. According to an embodiment, the red second pixel P2r, the green second pixel P2g, and the blue second pixel P2b in the second display area DA2 may have a different pixel arrangement from the red first pixel P1r, the green first pixel P1g, and the blue first pixel P1b in the first display area DA1.

According to an embodiment, the blue second pixel P2b and the red second pixel P2r may be alternately arranged in a first row 1N′, the green second pixels P2g may be arranged in a second row 2N′ spaced apart from each other by a certain distance, the second row 2N′ being adjacent to the first row 1N′. The blue second pixel P2b and the red second pixel P2r may be alternately arranged in a third row 3N′ adjacent to the second row 2N′, and the green second pixels P2g may be arranged in a fourth row 4N′ spaced apart from each other by a certain distance, the fourth row 4N′ being adjacent to the third row 3N′. Although the blue second pixel P2b and the red second pixel P2r are arranged in an alternating manner in each odd-numbered row, adjacent odd rows start with a different one of the blue and red second pixel P2b/P2r. Hence, in each odd-numbered column, the blue second pixel P2b and the red second pixel P2r are arranged in an alternating manner. The pixel arrangements in the first to fourth rows 1N′ to 4N′ described above may be repeated to the last row.

the positions of the blue second pixel P2b and the red second pixel P2r arranged in the first row 1N′ may be offset by a column in the x-direction with respect to the positions of the green second pixels P2g in the second row 2N′. For example, the blue second pixel P2b and the red second pixel P2r may be alternately arranged in odd-numbered column 1M′, 3M′, etc. while the green second pixels P2g may be arranged in even-numbered column 2M′, 4M′, etc. This results in the blue second pixel P2b and the red second pixel P2r being in a staggered arrangement with respect to the green second pixels P2g. The pixel arrangements in the first to fourth columns 1M′ to 4M′ described above may repeat to the last column.

The plurality of hole areas PH may be arranged in the second display area DA2. According to an embodiment, the hole areas PH may be arranged between the second pixels P2. The hole areas PH may be located between light-emitting diodes included in the second pixels P2 and may not overlap the light-emitting diodes.

According to an embodiment, a pixel circuit or circuit devices included in the pixel circuit and/or lines may not be arranged in the hole areas PH. Accordingly, the area (or the size) of the pixel circuit arranged in the second display area DA2 may be less than the area (or the size) of the pixel circuit arranged in the first display area DA1.

The hole area PH may not denote an actual hole formed in a substrate or an insulating layer. Rather, the hole area PH may be an area of a certain size having a shape of a hole, with a circuit device and/or lines not being arranged on the substrate when the hole area PH is viewed in a direction perpendicular to an upper surface of the substrate. This absence of circuit device and/or circuit lines from the hole area PH may be due to an arrangement, on the substrate, of the circuit device included in the pixel circuit and the lines connected to the pixel circuit.

The hole areas PH may be regularly arranged at constant intervals. According to an embodiment, the hole areas PH may be arranged in every other odd row and every other even column. For example, the hole areas PH may be positioned in the first row 1N′ and the third row 3N′ between the blue second pixel P2b and the red second pixel P2r adjacent to the blue second pixel P2b in a +x direction, and in the second column 2M′ and the fourth column 4M′ between the green second pixels P2g adjacent to each other. That is, the hole areas PH may be arranged in the first row 1N′ and the second column 2M′ and the third row 3N′ and the fourth column 4M′. According to an embodiment, the hole areas PH may be arranged between the adjacent second pixels P2 to be unequally distributed to one side. For example, as illustrated in FIG. 7, the hole areas PH may be arranged to be unequally distributed to one side (for example, in a −y direction) between the adjacent green second pixels P2g. The arrangement of the hole areas PH in the first to fourth rows 1N′ to 4N′ described above may repeat to the last row. The arrangement of the hole areas PH in the first to fourth columns 1M′ to 4M′ described above may repeat to the last column. However, the disclosure is not necessarily limited thereto. The arrangement of the hole areas PH may be changed.

According to an embodiment, the second pixels P2 in the second display area DA2 may have different shapes from the first pixels P1 in the first display area DA1. The red second pixel P2r, the green second pixel P2g, and the blue second pixel P2b may respectively have different shapes from the red first pixel P1r, the green first pixel P1g, and the blue first pixel P1b.

According to the embodiment of FIG. 7, the red second pixel P2r, the green second pixel P2g, and the blue second pixel P2b may have circular shapes. However, the disclosure is not limited thereto. According to another embodiment, the red second pixel P2r, the green second pixel P2g, and the blue second pixel P2b may have oval shapes or polygonal shapes. The polygonal shapes may include shapes having rounded vertices.

According to an embodiment, the hole area PH may have an oval shape. FIG. 7 illustrates that the hole area PH may have an oval shape, a major axis of which extends parallel to the x direction. However, the disclosure is not necessarily limited thereto. According to another embodiment, the hole area PH may have a circular shape or a polygonal shape. The location and the size of the hole area PH may be changed according to the structure and the arrangement of the pixel and the pixel circuit. Also, FIG. 7 illustrates that one hole area PH may be located between a pair of second pixels P2 adjacent to each other. However, according to cases, the plurality of hole areas PH may be located between a pair of second pixels P2 adjacent to each other.

FIG. 8 is a schematic cross-sectional view of the first display area DA1 of the display panel 10 according to an embodiment, and FIG. 9 is a schematic cross-sectional view of the second display area DA2 of the display panel 10 according to an embodiment.

FIGS. 8 and 9 illustrate a case where the display panel 10 includes an organic light-emitting diode as a display element. The organic light-emitting diode realizing a pixel may be arranged in each of the first display area DA1 and the second display area DA2. For convenience of explanation, the organic light-emitting diode of the first pixel P1 arranged in the first display area DA1 may be referred to as a first organic light-emitting diode OLED1, and the organic light-emitting diode of the second pixel P2 arranged in the second display area DA2 may be referred to as a second organic light-emitting diode OLED2.

Referring to FIGS. 8 and 9, the first organic light-emitting diode OLED1 and the second organic light-emitting diode OLED2 may be arranged on the substrate 100.

The substrate 100 may include a first base layer 101, a first barrier layer 102, a second base layer 103, and a second barrier layer 104. The first base layer 101 and the second base layer 103 may include polymer resins, and each of the first barrier layer 102 and the second barrier layer 104 may include an inorganic insulating material. The polymer resins may include polyether sulfone, polyacrylate, polyether imide, polyethylene naphthalate, polyethylene terephthalate, polyphenylene sulfide, polyarylate, polyimide, polycarbonate, and/or cellulose acetate propionate.

A buffer layer 111 may be arranged on the substrate 100. The buffer layer 111 may reduce or prevent the penetration of impurities, moisture, or external substances from below the substrate 100. The buffer layer 111 may include an inorganic insulating material, such as silicon oxide, silicon oxynitride, and silicon nitride, and may include a single-layered or multi-layered structure including the materials described above.

The light-blocking metal layer BML may be arranged between the substrate 100 and the buffer layer 111 and may be located in the first display area DA1 and the second display area DA2. The light-blocking metal layer BML may include conductive metal, such as Al, Pt, Pd, Ag, Mg, Au, Ni, Nd, Ir, Cr, Ca, Mo, Ti, W, an/or Cu. The light-blocking metal layer BML may make up a portion of a pixel circuit PC.

Each of the first organic light-emitting diode OLED1 and the second organic light-emitting diode OLED2 may be electrically connected to the pixel circuit PC. The first organic light-emitting diode OLED1 may be electrically connected to the pixel circuit PC between the substrate 100 and the first organic light-emitting diode OLED1, and the second organic light-emitting diode OLED2 may be electrically connected to the pixel circuit PC between the substrate 100 and the second organic light-emitting diode OLED2.

The pixel circuit PC may include a thin-film transistor TFT, a capacitor Cst, and lines connected to the thin-film transistor TFT and the capacitor Cst. The thin-film transistor TFT may include a semiconductor layer Act, a gate electrode GE overlapping a channel area of the semiconductor layer Act, and a source electrode SE and a drain electrode DE connected to a source area and a drain area of the semiconductor layer Act, respectively. A first gate insulating layer 113 may be arranged between the semiconductor layer Act and the gate electrode GE, and a second gate insulating layer 115 and an interlayer insulating layer 117 may be arranged between the gate electrode GE and the source electrode SE and between the gate electrode GE and the drain electrode DE. A planarization layer 119 may be arranged on the source electrode SE and the drain electrode DE.

The semiconductor layer Act may include polysilicon. According to some embodiments, the semiconductor layer Act may include amorphous silicon. According to some embodiments, the semiconductor layer Act may include an oxide semiconductor including at least one material selected from the group consisting of In, Ga, Sn, Zr, V, Hf, Cd, Ge, Cr, Ti, and Zn. The semiconductor layer Act may include a channel area, and a source area and a drain area doped with impurities.

The capacitor Cst may be arranged to overlap the thin-film transistor TFT. The capacitor Cst may include a lower electrode CE1 and an upper electrode CE2 overlapping each other. According to some embodiments, the gate electrode GE of the thin-film transistor TFT may include the lower electrode CE1 of the capacitor Cst.

The gate electrode GE or the lower electrode CE1 may include a low-resistance conductive material, such as Mo, Al, Cu, and/or Ti, and may include a single-layered or multi-layered structure including the materials described above.

The upper electrode CE2 may include Al, Pt, Pd, Ag, Mg, Au, Ni, Nd, Ir, Cr, Ca, Mo, Ti, W, and/or Cu and may include a single-layered or multi-layered structure including the materials described above. The second gate insulating layer 115 may be arranged between the lower electrode CE1 and the upper electrode CE2.

The source electrode SE and/or the drain electrode DE may include Al, Pt, Pd, Ag, Mg, Au, Ni, Nd, Ir, Cr, Ca, Mo, Ti, W, and/or Cu and may include a single-layered or multi-layered structure including the materials described above. For example, the source electrode SE and/or the drain electrode DE may have a triple-layered structure including a Ti layer/an Al layer/a Ti layer.

Each of the first gate insulating layer 113, the second gate insulating layer 115, and the interlayer insulating layer 117 may include an inorganic insulating material, such as silicon oxide, silicon oxynitride, and silicon nitride, and may include a single-layered or multi-layered structure including the materials described above.

The planarization layer 119 may be arranged on the interlayer insulating layer 117. The planarization layer 119 may include an organic material, such as acryl, benzocyclobutene (BCB), PI, or hexamethyldisiloxane (HMDSO). Alternatively, the planarization layer 119 may include an inorganic material. The planarization layer 119 may have a flat upper portion. The planarization layer 119 may include a single layer or multiple layers.

A plurality of lines (not shown) may be arranged between the first gate insulating layer 113, the second gate insulating layer 115, the interlayer insulating layer 117, and the planarization layer 119. The plurality of lines may include a data line, a scan line, an emission control line, etc. connected to the thin-film transistor TFT and the capacitor Cst.

A connection electrode CM may be arranged on the planarization layer 119. Through the connection electrode CM, the thin-film transistor TFT may be electrically connected to a first electrode 210 of the respective organic light-emitting diode. The connection electrode CM may be connected to the thin-film transistor TFT through a contact hole of the planarization layer 119, and the first electrode 210 may be connected to the connection electrode CM through the contact hole in the planarization layer 119.

Each of the first organic light-emitting diode OLED1 and the second organic light-emitting diode OLED2 may have a structure in which the first electrode 210, which is a pixel electrode, an emission layer 222, and a second electrode 230, which is an opposite electrode, overlap one another. The overlapping structure described above may include a first functional layer 221 between the first electrode 210 and the emission layer 222 and/or a second functional layer 223 between the emission layer 222 and the second electrode 230.

The first electrode 210 may be arranged on the planarization layer 119. The first electrode 210 may include a reflective layer including Ag, Mg, Al, Pt, Pd, Au, Ni, Nd, Ir, Cr, or a compound thereof. The first electrode 210 may include a reflective layer including the materials described above and a transparent conductive layer arranged above or/and below the reflective layer. The transparent conductive layer may include indium tin oxide (ITO), indium zinc oxide (IZO), zinc oxide (ZnO), indium oxide (In2O3), indium gallium oxide (IGO), or aluminum zinc oxide (AZO). According to an embodiment, the first electrode 210 may have a tri-layered structure of ITO/Ag/ITO layers.

A bank layer 123 may cover an edge of the first electrode 210 and may include an opening overlapping the first electrode 210. FIGS. 8 and 9 illustrate an opening (hereinafter, referred to as a first bank opening 123OP1) overlapping the first electrode 210 of the first organic light-emitting diode OLED1 of the first pixel P1 and an opening (hereinafter, referred to as a second bank opening 123OP2) overlapping the first electrode 210 of the second organic light-emitting diode OLED2 of the second pixel P2.

The first bank opening 123OP1 and the second bank opening 123OP2 of the bank layer 123 may define emission areas of the first organic light-emitting diode OLED1 and the second organic light-emitting diode OLED2, respectively. As described above, the width (or the size) of the first bank opening 123OP1 of the bank layer 123 may be substantially the same as the width (or the size) of a first emission area EA1 of the first organic light-emitting diode OLED1, and the width (or the size) of the second bank opening 123OP2 of the bank layer 123 may be substantially the same as the width (or the size) of a second emission area EA2 of the second organic light-emitting diode OLED2. The first emission area EA1 of the first organic light-emitting diode OLED1 may indicate the width (or the size) of the first pixel P1. The second emission area EA2 of the second organic light-emitting diode OLED2 may indicate the width (or the size) of the second pixel P2.

According to an embodiment, the bank layer 123 may include a colored non-transparent light-blocking insulating layer and may be, for example, black. For example, the bank layer 123 may include a PI-based binder and a pigment in which red, green, and blue colors are combined. Alternatively, the bank layer 123 may include a cardo-based binder resin and a mixture of a lactam-based black pigment and a blue pigment. Alternatively, the bank layer 123 may include carbon black. The bank layer 123 may prevent external light from entering the display panel 10 along with the reflection preventive layer 600 (which will be described below), and may increase contrast of the display panel 10.

The emission layer 222 may be located in each of the first bank opening 123OP1 and the second bank opening 123OP2 of the bank layer 123 and may overlap the first electrode 210. The emission layer 222 may include a high molecular-weight or a low molecular-weight organic material emitting light of a certain color. The first functional layer 221 and the second functional layer 223 may be formed below and above the emission layer 222, respectively.

The first functional layer 221 may include a hole transport layer (HTL) and/or a hole injection layer (HIL). The second functional layer 223 may include an electron transport layer (ETL) and/or an electron injection layer (EIL). The first functional layer 221 and/or the second functional layer 223 may be formed throughout the substrate 100 unlike the emission layer 222. In other words, the first functional layer 221 and/or the second functional layer 223 may cover the first display area DA1 and the second display area DA2.

The thin-film encapsulation layer 300 may cover the first and second organic light-emitting diodes OLED1 and OLED2. According to an embodiment, the thin-film encapsulation layer 300 may include a first inorganic encapsulation layer 310, a second inorganic encapsulation layer 330, and an organic encapsulation layer 320 therebetween.

Each of the first and second inorganic encapsulation layers 310 and 330 may include at least one inorganic insulating material. The inorganic insulating material may include aluminum oxide, titanium oxide, tantalum oxide, hafnium oxide, zinc oxide, silicon oxide, silicon nitride, and/or silicon oxynitride.

The organic encapsulation layer 320 may include a polymer-based material. The polymer-based material may include acryl-based resins, epoxy-based resins, polyimide, polyethylene, etc. For example, the organic encapsulation layer 320 may include acryl-based resins, for example, polymethylmethacrylate, polyacrylic acid, etc. The organic encapsulation layer 320 may be formed by curing a monomer or by being coated with a polymer.

The input sensing layer 400 may include a touch electrode, and the touch electrode may include a conductive layer ML. The touch electrode may include the conductive layer ML having a mesh structure surrounding the emission areas of the first and second organic light-emitting diodes OLED1 and OLED2 in a plan view. As illustrated in FIGS. 8 and 9, the conductive layer ML may include a connection structure of a first conductive layer ML1 and a second conductive layer ML2. According to another embodiment, the conductive layer ML may include any one of the first conductive layer ML1 and the second conductive layer ML2. The conductive layer ML may include Mo, Mb, Ag, Ti, Cu, Al, and an alloy thereof.

The input sensing layer 400 may include a first touch insulating layer 401 on the thin-film encapsulation layer 300, a second touch insulating layer 403 on the first touch insulating layer 401, and a third touch insulating layer 405 on the second touch insulating layer 403. The first conductive layer ML1 may be arranged between a first touch insulating layer 401 and a second touch insulating layer 403, and the second conductive layer ML2 may be arranged between the second touch insulating layer 403 and a third touch insulating layer 405.

The first to third touch insulating layers 401, 403, and 405 may include an inorganic insulating material and/or an organic insulating material. According to an embodiment, the first touch insulating layer 401 and the second touch insulating layer 403 may include an inorganic insulating material, and the third touch insulating layer 405 may include an organic insulating material.

The reflection preventive layer 600 may include only the plurality of color filters 620.

According to an embodiment, a blue color filter 620B, a red color filter 620R, and a green color filter 620G may be sequentially stacked in a direction (a +z direction) away from the substrate 100. According to another embodiment, the stacking order of the blue color filter 620B, the red color filter 620R, and the green color filter 620G may be changed.

The blue color filter 620B may transmit most of blue light and block most of red light or green light. The blue color filter 620B may include first openings 620BOP1 above the first emission area EA1 of the red first pixel P1r and the first emission area EA1 of the green first pixel P1g, respectively. The blue color filter 620B may include second openings 620BOP2 above the second emission area EA2 of the red second pixel P2r and the second emission area EA2 of the green second pixel P2g, respectively. Most of blue light emitted from the first emission area EA1 of the blue first pixel P1b and the second emission area EA2 of the blue second pixel P2b may be transmitted through the blue color filter 620B to the outside.

The red color filter 620R may transmit most of red light and block most of blue light or green light. The red color filter 620R may include first openings 620ROP1 above the first emission area EA1 of the blue first pixel P1b and the first emission area EA1 of the green first pixel P1g, respectively. The red color filter 620R may include second openings 620ROP2 above the second emission area EA2 of the blue second pixel P2b and the second emission area EA2 of the green second pixel P2g, respectively. Most of red light emitted from the first emission area EA1 of the red first pixel P1r and the second emission area EA2 of the red second pixel P2r may be transmitted through the red color filter 620R to the outside.

The green color filter 620G may transmit most of green light and block most of blue light or red light. The green color filter 620G may include first openings 620GOP1 above the first emission area EA1 of the red first pixel P1r and the first emission area EA1 of the blue first pixel P1b. The green color filter 620G may include second openings 620GOP2 above the second emission area EA2 of the red second pixel P2r and the second emission area EA2 of the blue second pixel P2b. Most of green light emitted from the first emission area EA1 of the green first pixel P1g and the second emission area EA2 of the green second pixel P2g may be transmitted through the green color filter 620G to the outside.

The reflection preventive layer 600 may include light-blocking portions BP defined between the first emission areas EA1 and between the second emission areas EA2 by the blue color filter 620B, the red color filter 620R, and the green color filter 620G overlapping each other. The light-blocking portions BP may not include a black light-blocking material, but may block light through the overlapping color filters. The light-blocking portions BP may reduce reflection of external light of the display panel 10.

Also, according to an embodiment, in the red first pixel Pr, the width (or the size) of the first opening 620GOP1 in the green color filter 620G above the first emission area EA1 may be greater than the width (or the size) of the first opening 620BOP1 in the blue color filter 620B that is above the first emission area EA1. In the red second pixel P2r, the width (or the size) of the second opening 620GOP2 in the green color filter 620G above the second emission area EA2 may be greater than the width (or the size) of the second opening 620BOP2 in the blue color filter 620B above the second emission area EA2.

In the green first pixel P1g, the width (or the size) of the first opening 620ROP1 in the red color filter 620R that is above the first emission area EA1 may be greater than the width (or the size) of the first opening 620BOP1 in the blue color filter 620B that is above the first emission area EA1. In the green second pixel P2g, the width (or the size) of the second opening 620ROP2 in the red color filter 620R above the second emission area EA2 of may be greater than the width (or the size) of the second opening 620BOP2 in the blue color filter 620B above the second emission area EA2.

In the blue first pixel P1b, the width (or the size) of the first opening 620GOP1 in the green color filter 620G above the first emission area EA1 may be greater than the width (or the size) of the first opening 620ROP1 in the red color filter 620R that is above the first emission area EA1. In the blue second pixel P2b, the width (or the size) of the second opening 620GOP2 in the green color filter 620G above the second emission area EA2 of may be greater than the width (or the size) of the second opening 620ROP2 in the red color filter 620R that is above the second emission area EA2.

The overcoat layer 630 may be arranged on the color filters 620. The overcoat layer 630 may include a transmissive layer not having colors of a visible light band and may planarize an upper surface of the light-blocking layer 610 and upper surfaces of the color filters 620. The overcoat layer 630 may include a transmissive organic material, such as acryl-based resins.

Referring to FIG. 9, the hole area PH may be located between two neighboring second organic light-emitting diodes OLED2 of the plurality of second organic light-emitting diodes OLED2 arranged in the second display area DA2. As described above, the hole area PH may be an area having a predetermined size, marked by an absence of circuit devices, such as the thin-film transistor TFT, etc. included in the pixel circuit, and/or the lines connected to the circuit devices.

The bank layer 123 may include an opening (hereinafter, a third bank opening 123OP3) above the hole area PH. Each of the color filters 620 of the reflection preventive layer 600 may include an opening above the hole area PH. The blue color filter 620B may include a third opening 620BOP3 above the hole area PH, for example one third opening 620BOP3 above each of the hole areas PH. The red color filter 620R may include a third opening 620ROP3 above the hole area PH, for example one third opening 620ROP3 above each of the hole areas PH. The green color filter 620G may include a third opening 620GOP3 above the hole area PH, for example one third opening 620GOP3 above each of the hole areas PH.

The color filters 620 may not be provided in the hole area PH, and a portion of the overcoat layer 630 may be located in the hole area PH. For example, the overcoat layer 630 may fill at least a portion of each of the third opening 620BOP3 in the blue color filter 620B, the third opening 620ROP3 in the red color filter 620R, and the third opening 620GOP3 in the green color filter 620G and may entirely cover the color filters 620.

According to an embodiment, the width (or the size) of the third opening 620BOP3 in the blue color filter 620B above the hole area PH may be greater than the width (or the size) of the third opening 620ROP3 in the red color filter 620R above the hole area PH. The width (or the size) of the third opening 620GOP3 in the green color filter 620G above the hole area PH may be greater than the width (or the size) of the third opening 620BOP3 in the blue color filter 620B above the hole area PH.

The first and second functional layers 221 and 223 may also be provided above the hole area PH. On the contrary, the second electrode 230 including a metal element may include an opening 230OP in the hole area PH. The transmittance of the hole area PH may be improved by the opening 230OP of the second electrode 230. The size (or the width) of the opening 230OP of the second electrode 230 may be less than the size (or the width) of the third bank opening 123OP3 in the bank layer 123.

The pixel circuit, the lines, the bank layer 123 including a non-transparent material, and the color filters 620 may not be provided in an area of the display panel 10 in the hole area PH, and thus, the transmittance of the second display area DA2 may be improved.

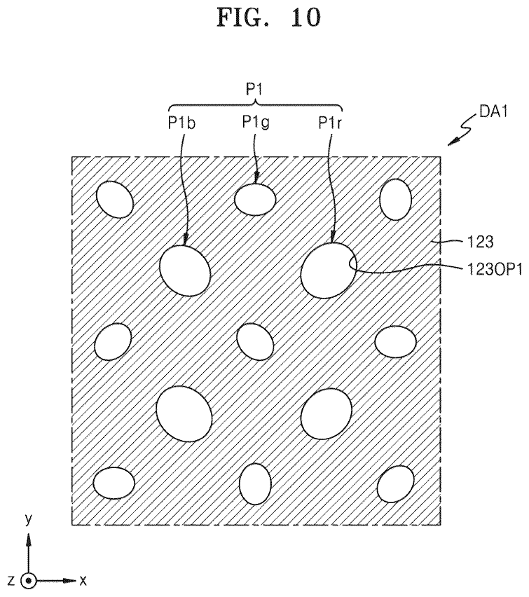

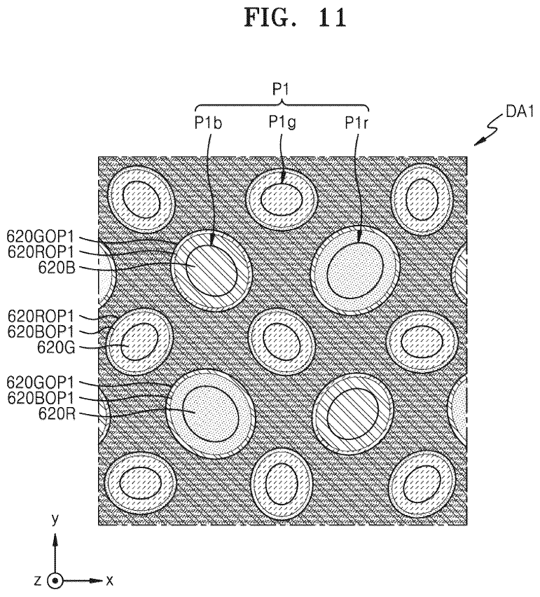

FIG. 10 is a schematic plan view of a display layer of the first display area DA1 of the display panel 10 according to an embodiment, and FIG. 11 is a schematic plan view of the reflection preventive layer 600 of the first display area DA1 of the display panel 10 according to an embodiment.

Referring to FIGS. 8, 10, and 11, in the first display area DA1, the first openings in the color filters 620 of the reflection preventive layer 600 may align with the first bank openings 123OP1 of the bank layer 123.

The width (or the size) of each of the first openings 620BOP1 in the blue color filter 620B may be greater than the width (or the size) of the respective first bank opening 123OP1 in the bank layer 123. The width (or the size) of each of the first openings 620ROP1 in the red color filter 620R may be greater than the width (or the size) of the respective first bank opening 123OP1 in the bank layer 123. The width (or the size) of each of the first openings 620GOP1 in the green color filter 620G may be greater than the width (or the size) of the respective first bank opening 123OP1 in the bank layer 123.

The shape of each of the first openings 620BOP1 in the blue color filter 620B may be substantially the same as the shape of the respective first bank opening 123OP1 in the bank layer 123. The shape of each of the first openings 620ROP1 in the red color filter 620R may be substantially the same as the shape of the respective first bank opening 123OP1 in the bank layer 123. The shape of each of the first openings 620GOP1 in the green color filter 620G may be substantially the same as the shape of the respective first bank opening 123OP1 in the bank layer 123.

As described above, the first bank openings 123OP1 of the bank layer 123 may define the first emission areas EA1 of the first pixels P1. According to an embodiment, the first pixels P1 may have the planar shape and arrangement structure of FIG. 6, and thus, the first openings 620BOP1 in the blue color filter 620B, the first openings 620ROP1 in the red color filter 620R, and the first openings 620GOP1 in the green color filter 620G may have oval shapes.

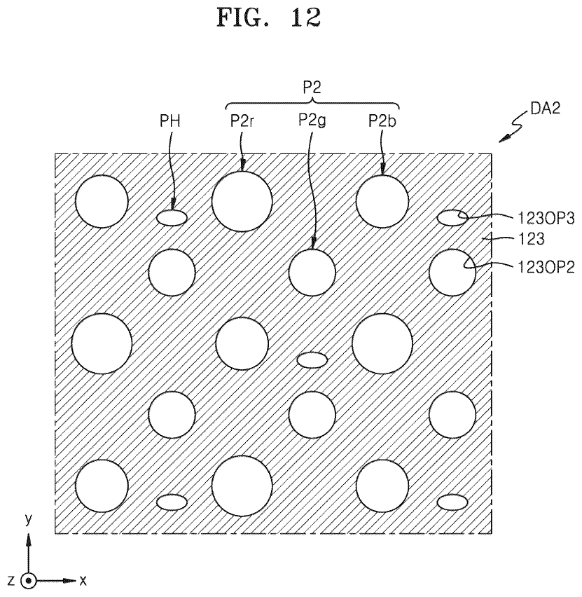

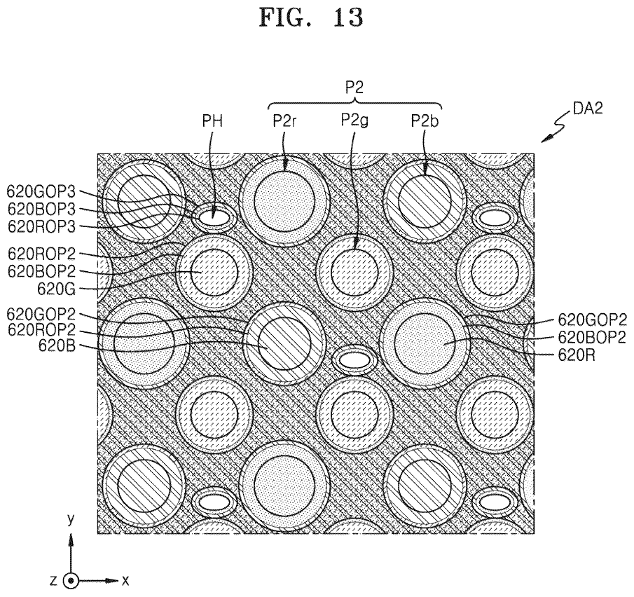

FIG. 12 is a schematic plan view of a display layer of the second display area DA2 of the display panel 10 according to an embodiment, and FIG. 13 is a schematic plan view of the reflection preventive layer 600 of the second display area DA2 of the display panel 10 according to an embodiment.

Referring to FIGS. 9, 10, and 11, in the second display area DA2, the second openings in the color filters 620 of the reflection preventive layer 600 may align with the second bank openings 123OP2 in the bank layer 123, respectively.

The width (or the size) of each of the second openings 620BOP2 in the blue color filter 620B may be greater than the width (or the size) of the respective second bank opening 123OP2 in the bank layer 123. The width (or the size) of each of the second openings 620ROP2 in the red color filter 620R may be greater than the width (or the size) of the respective second bank opening 123OP2 in the bank layer 123. The width (or the size) of each of the second openings 620GOP2 in the green color filter 620G may be greater than the width (or the size) of the respective second bank opening 123OP2 in the bank layer 123.

The shape of each of the second openings 620BOP2 in the blue color filter 620B may be substantially the same as the shape of the respective second bank opening 123OP2 in the bank layer 123. The shape of each of the second openings 620ROP2 of the red color filter 620R may be substantially the same as the shape of the respective second bank opening 123OP2 in the bank layer 123. The shape of each of the second openings 620GOP2 in the green color filter 620G may be substantially the same as the shape of the respective second bank opening 123OP2 in the bank layer 123.

As described above, the second bank openings 123OP2 in the bank layer 123 may define the second emission areas EA2 of the second pixel P2. According to an embodiment, the second pixels P2 may have the planar shape and arrangement structure of FIG. 7, and thus, the second openings 620BOP2 in the blue color filter 620B, the second openings 620ROP2 in the red color filter 620R, and the second openings 620GOP2 in the green color filter 620G may have circular shapes.

Also, in the second display area DA2, the third openings in the color filters 620 of the reflection preventive layer 600 may be above the third bank openings 123OP3 formed in the bank layer 123, respectively.

The width (or the size) of each of the third openings 620BOP3 in the blue color filter 620B may be greater than the width (or the size) of the respective third bank opening 123OP3 in the bank layer 123. The width (or the size) of each of the third openings 620ROP3 in the red color filter 620R may be greater than the width (or the size) of the respective third bank opening 123OP3 in the bank layer 123. The width (or the size) of each of the third openings 620GOP3 i the green color filter 620G may be greater than the width (or the size) in the respective third bank opening 123OP3 of the bank layer 123.

The shape of each of the third openings 620BOP3 in the blue color filter 620B may be substantially the same as the shape of the respective third bank opening 123OP3 in the bank layer 123. The shape of each of the third openings 620ROP3 in the red color filter 620R may be substantially the same as the shape of the respective third bank opening 123OP3 in the bank layer 123. The shape of each of the third openings 620GOP3 in the green color filter 620G may be substantially the same as the shape of the respective third bank opening 123OP3 in the bank layer 123.

According to an embodiment, the third bank openings 123OP3 in the bank layer 123 may define the hole areas PH as described above. According to an embodiment, the hole areas PH may have the planar shape and arrangement structure of FIG. 7. Thus, the third openings 620BOP3 in the blue color filter 620B, the third openings 620ROP3 in the red color filter 620R, and the third openings 620GOP3 in the green color filter 620G may have oval shapes that match the oval shapes of the hole areas PH.

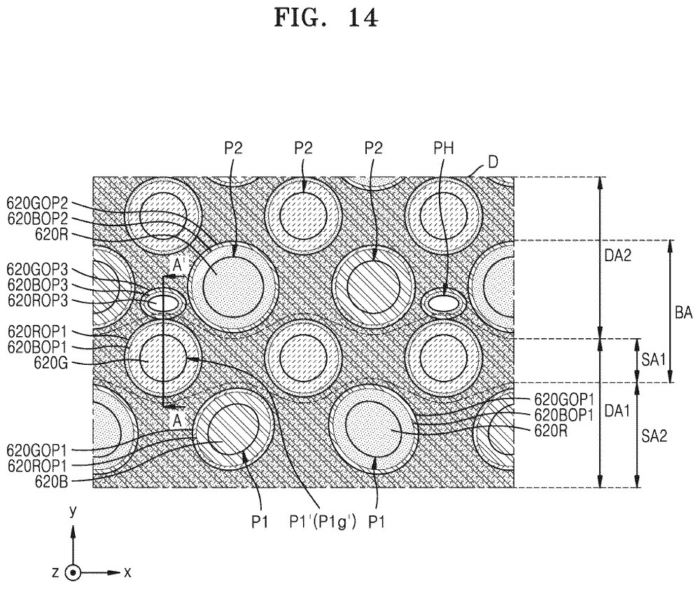

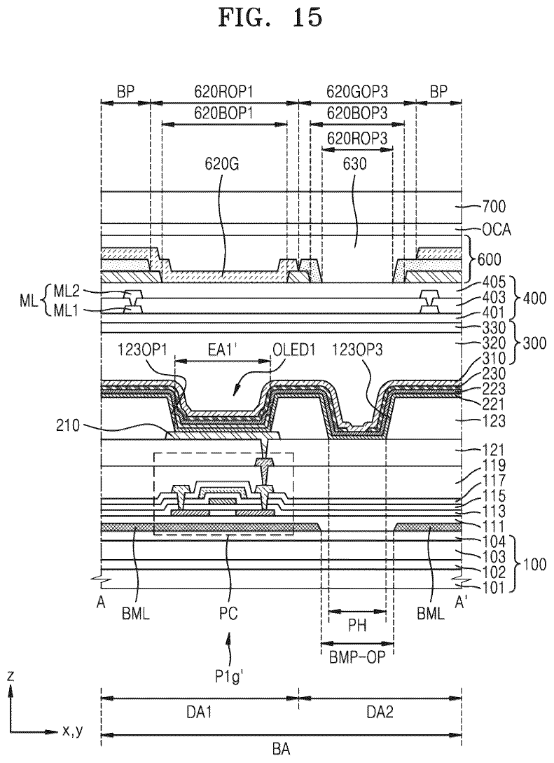

FIG. 14 is a schematic plan view of a portion, that is, region D of FIG. 5, of the display panel 10 according to an embodiment. FIG. 15 is a schematic cross-sectional view of a portion of the display panel 10, taken along line A-A′ of FIG. 10, according to an embodiment.

FIG. 14 is an enlarged plan view of a portion of a boundary area between the first display area DA1 and the second display area DA2 and illustrates a portion of the first display area DA1 in contact with the second display area DA2 in a direction (for example, a −y direction).

Referring to FIGS. 14 and 15, first pixels P1 and P1′ may be arranged in the first display area DA1. The first display area DA1 may include a first sub-area SA1 in contact with the second display area DA2 and a second sub-area SA2 outside the first sub-area SA1. The second sub-area SA2 may be an area apart from the second display area DA2.

According to an embodiment, the first sub-area SA1 may be part of the first display area DA1 that is also in contact with the second display area DA2. Also, in the first sub-area SA1, there may be the first pixels P1′ in at least one column and/or at least one row adjacent to the second pixels P2 of the second display area DA2 and the hole areas PH. For example, the first pixels P1′ of one column and/or one row adjacent to the second pixels P2 of the second display area DA2 and the hole areas PH may be arranged in the first sub-area SA1.

At least some of the first pixels P1′ arranged in the first sub-area SA1 of the first display area DA1 may be respectively arranged to be adjacent to at least some of the hole areas PH of the second display area DA2. That is, at least some of the first pixels P1′ arranged in the first sub-area SA1 of the first display area DA1 may be adjacent to the hole areas PH in a boundary area BA.

At least one of the shape and the arrangement of the first pixels P1′ of the first sub-area SA1 may be provided to be different from the shape and/or the arrangement of the first pixels P1 of the second sub-area SA2.

According to an embodiment, the shape of the first pixels P1′ of the first sub-area SA1 may be different from the shape of the first pixels P1 of the second sub-area SA2. According to an embodiment, the shape of the first pixels P1′ of the first sub-area SA1 may be the same as the shape of the second pixels P2 of the second display area DA2.

As illustrated in FIGS. 11, 13, and 14, the first pixels P1 of the second sub-area SA2 may be provided to have oval shapes, and the first pixels P1 of the second sub-area SA2 may include the plurality of first pixels P1 having the oval shapes, axes of which are oriented in different directions, wherein the plurality of first pixels P1 may be irregularly or regularly arranged in the second sub-area SA2. The second pixels P2 of the second display area DA2 may be provided to have circular shapes. The first pixels P1′ of the first sub-area SA1 may have the same circular shapes as the second pixels P2 of the second display area DA2.

Referring to FIGS. 14 and 15, in a plan view, the first openings in the color filters 620 overlapping the first pixels P1′ of the first sub-area SA1 may be in contact with or apart from the third openings of the color filters 620 overlapping the hole areas PH of the second display area DA2 adjacent to the first sub-area SA1. Some of the first pixels P1′ of the first sub-area SA1 may be adjacent to the hole areas PH of the second display area DA2. For example, in the embodiment of FIG. 14, the first pixels P1′ of the first sub-area SA1 may include green first pixels P1g′, and some of the green first pixels P1g′ may be adjacent to the hole areas PH of the second display area DA2 in a first direction (for example, a y direction).

Hereinafter, it is assumed that the green first pixel P1g′ and the hole areas PH are adjacent to each other.

According to an embodiment, the first opening 620ROP1 in the red color filter 620R above an emission area EA1′ of the green first pixel P1g′ may be apart from the third opening 620ROP3 in the red color filter 620R and the third opening 620BOP3 in the blue color filter 620B above the hole area PH adjacent to the green first pixel P1g′ and may be in contact with the third opening 620GOP3 in the green color filter 620G.

A portion of the blue color filter 620B arranged between the first opening 620BOP1 in the blue color filter 620B above the emission area EA1′ of the green first pixel P1g′ and the third opening 620BOP3 in the blue color filter 620B above the hole area PH may be covered by at least one of the red color filter 620R and the green color filter 620G. That is, the portion of the blue color filter 620B arranged between the first opening 620BOP1 in the blue color filter 620B above the emission area EA1′ of the green first pixel P1g′ and the third opening 620BOP3 in the blue color filter 620B in the hole area PH may overlap the red color filter 620R or the green color filter 620G. An upper surface of the portion of the blue color filter 620B may not be exposed. The portion of the blue color filter 620B may overlap a body portion of the bank layer 123. The portion of the blue color filter 620B may overlap at least one of the red color filter 620R and the green color filter 620G, and may block light.

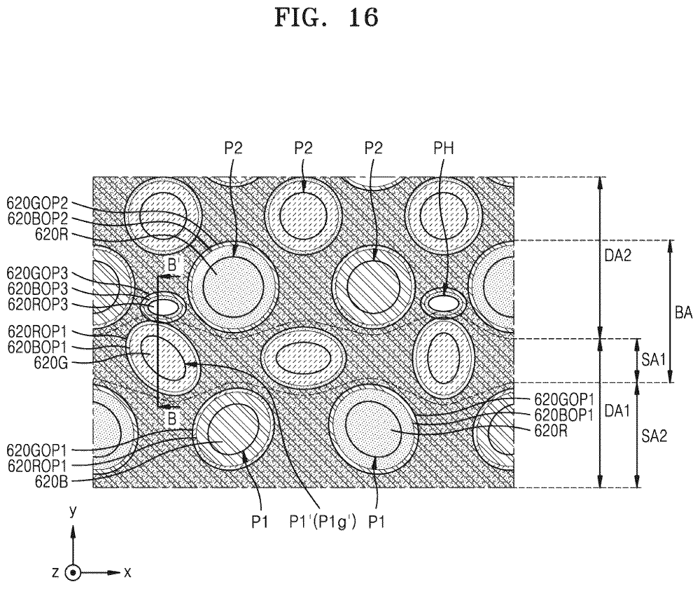

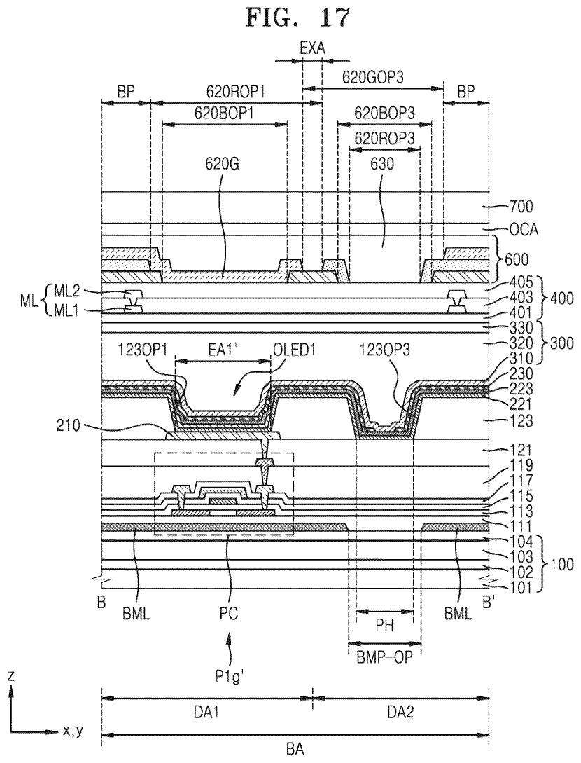

FIG. 16 is a schematic plan view of a portion of a display panel according to a comparative embodiment, and FIG. 17 is a schematic cross-sectional view of the portion of the display panel, taken along line B-B′ of FIG. 16, according to the comparative embodiment.

Referring to FIGS. 16 and 17, at least some of the first pixels P1′ in the first sub-area SA1 may be adjacent to the hole areas PH in the boundary area BA from among the hole areas PH of the second display area DA2. For example, FIG. 16 illustrates that the first pixels P1′ of the first sub-area SA1 may include the green first pixels P1g′, and some of the green first pixels P1g′ may be adjacent to the hole areas PH of the second display area DA2 in a first direction (for example, a y direction).

According to the comparative embodiment, the planar shape and arrangement of the first pixels P1′ of the first sub-area SA1 may be the same as the planar shape and arrangement of the first pixels P1 of the second sub-area SA2. The planar shape and arrangement of the first pixels P1 and P1′ of the first display area DA1 may be different from the planar shape and arrangement of the second pixels P2 of the second display area DA2.

As illustrated in FIGS. 11 and 13, the first pixels P1 and P1′ of the first sub-area SA1 and the second sub-area SA2 may be provided to have oval shapes, and the first pixels P1 and P1′ of the first sub-area SA1 and the second sub-area SA2 may include the plurality of first pixels P1 and P1′ having oval shapes, with axes oriented in different directions, wherein the plurality of first pixels P1 and P1′ may be irregularly or regularly arranged in the first sub-area SA1 and the second sub-area SA2. For example, the first pixels P1 and P1′ of the first and second sub-areas SA1 and SA2 may include the green first pixels P1g and P1g′, and the green first pixels P1g and P1g′ may include the first-axis green first pixel P1g-1, the second-axis green first pixel P1g-2, the third-axis green first pixel P1g-3, and the fourth-axis green first pixel P1g-4 having oval shapes, major axes of which are oriented in different directions, as described above with reference to FIG. 6. The first-axis green first pixel P1g-1, the second-axis green first pixel P1g-2, the third-axis green first pixel P1g-3, and the fourth-axis green first pixel P1g-4 may be irregularly arranged. The second pixels P2 of the second display area DA2 may be provided to have circular shapes.

A distance between the green first pixel P1g′ and the hole area PH arranged to be adjacent to each other may vary according to a direction of the major axis of each of the green first pixels P1g′ arranged in the first sub-area SA1. For example, FIG. 16 illustrates that the green first pixels P1g′ of the first sub-area SA1 arranged to be adjacent to the hole area PH may include the first-axis green first pixel P1g-1 having a major axis extending in the first direction (for example, the y direction) and the second-axis green first pixel P1g-2 including an element having a major axis extending in the first direction (for example, the y direction).

Hereinafter, descriptions are given based on the assumption that the green first pixel P1g′ (for example, the second-axis green first pixel P1g-2) and the hole area PH are arranged to be adjacent to each other.

The first opening 620ROP1 in the red color filter 620R above the emission area EA1′ of the green first pixel P1g′ and the third opening 620GOP3 in the green color filter 620G that is above the hole area PH may both extend into a certain area EXA.

A portion of the blue color filter 620B arranged in the area EXA between the first opening 620BOP1 above the emission area EA1′ of the green first pixel P1g′ and the third opening 620BOP3 above the hole area PH, may not be covered by the red color filter 620R or the green color filter 620G. An upper surface of the portion of the blue color filter 620B may not be covered by another color filter layer in the area EXA. Blue light may be transmitted or external light may be reflected through the portion of the blue color filter 620R in the area EXA, compromising the reliability of the display panel.

However, referring to FIGS. 14 to 17, according to an embodiment, the shape of the first pixels P1′ in the first sub-area SA1 may be different from the shape of the first pixels P1 in the second sub-area SA2, unlike the comparative embodiment. Also, the shape of the first pixels P1′ of the first sub-area SA1 may be the same as the shape of the second pixels P2 of the second display area DA2. For example, the first pixels P1′ of the first sub-area SA1 may be provided to have the same circular shape as the second pixels P2 of the second display area DA2 (e.g., in the embodiment of FIG. 14). Thus, unnecessarily exposure of at least some of the color filters 620 of the reflection preventive layer 600 around the hole area PH at a boundary area of the first display area DA1 and the second sub-area SA2 may be avoided. Thus, the reliability of the display panel 10 may be improved.

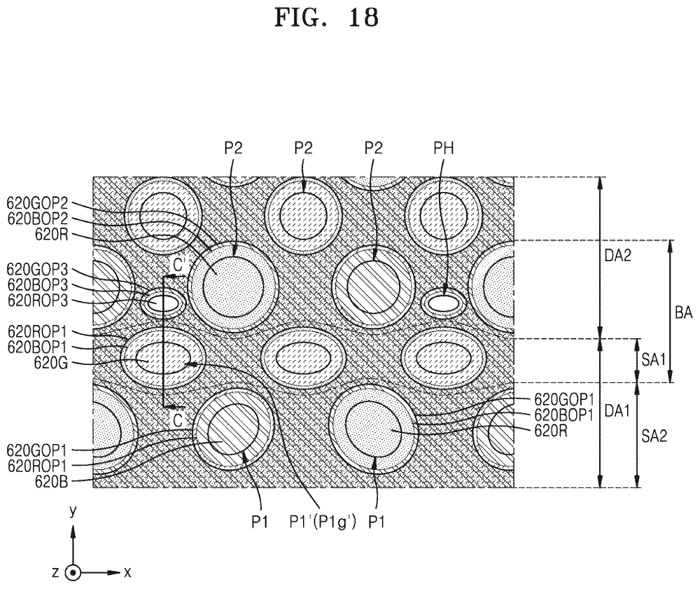

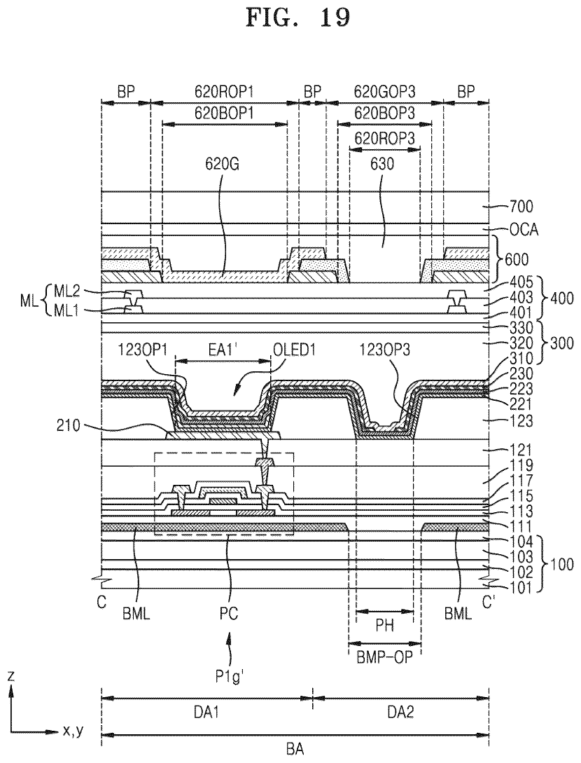

FIG. 18 is a schematic plan view of a portion of the display panel 10 according to an embodiment. FIG. 19 is a schematic cross-sectional view of a portion of the display panel 10, taken along line C-C′ of FIG. 18, according to an embodiment. FIGS. 18 and 19 are modified embodiments of FIGS. 14 and 15. Hereinafter, different aspects are mainly described and the same descriptions are not repeated.

Referring to FIGS. 18 and 19, at least some of the first pixels P1′ in the first sub-area SA1 may be respectively arranged to be adjacent to the hole areas PH in the boundary area BA. For example, FIG. 18 illustrates that the first pixels P1′ of the first sub-area SA1 may include the green first pixels P1g′, and some of the green first pixels P1g′ may be adjacent to the hole areas PH of the second display area DA2 in a first direction (for example, a y direction).

At least one of the shape and arrangement of the first pixels P1′ of the first sub-area SA1 may be provided to be different from the shape and/or the arrangement of the first pixels P1 of the second sub-area SA2.

According to an embodiment, the arrangement of the first pixels P1′ of the first sub-area SA1 may be different from the arrangement of the first pixels P1 of the second sub-area SA2. For example, the orientation of major axes of the first pixels P1′ of the first sub-area SA1 may be different from the orientation of major axes of the first pixels P1 of the second sub-area SA2. According to an embodiment, the shape of the first pixels P1′ of the first sub-area SA1 may be different from the shape of the second pixels P2 of the second display area DA2.

As illustrated in FIGS. 11, 13, and 14, the first pixels P1 of the second sub-area SA2 may have oval shapes, and the plurality of first pixels P1 having oval shapes have axes that are oriented in different directions. The plurality of first pixels P1 may be irregularly or regularly arranged in the second sub-area SA2. For example, the first pixels P1 of the second sub-area SA2 may include the green first pixels P1g, and the green first pixels P1g may include the first-axis green first pixel P1g-1, the second-axis green first pixel P1g-2, the third-axis green first pixel P1g-3, and the fourth-axis green first pixel P1g-4 having oval shapes, major axes of which are oriented in different directions, as described above with reference to FIG. 6. The first-axis green first pixel P1g-1, the second-axis green first pixel P1g-2, the third-axis green first pixel P1g-3, and the fourth-axis green first pixel P1g-4 may be irregularly arranged. The second pixels P2 of the second display area DA2 may be provided to have circular shapes.

According to an embodiment, the first pixels P1′ of the first sub-area SA1 may have oval shapes, but unlike in the second sub-area SA2, may have oval shapes with axes oriented in the same direction. The major axes of the first pixels P1′ of the first sub-area SA1 may extend in a second direction (for example, an x direction) perpendicular to the first direction (for example, the y direction).

According to an embodiment, the hole area PH may be provided to have an oval shape. For example, a major axis of the hole area PH may extend in the second direction (for example, the x direction). According to an embodiment, the direction of the major axes of the first pixels P1′ of the first sub-area SA1 may be the same as the direction of the major axes of the hole areas PH.

Some of the first pixels P1′ of the first sub-area SA1 may be adjacent to the hole areas PH of the second display area DA2. For example, as illustrated in FIG. 18, some of the green first pixels P1g′ of the first sub-area SA1 may be adjacent to the hole areas PH in the second display area DA2 in the first direction (for example, the y direction).

Hereinafter, it is assumed that the green first pixel P1g′ and the hole area PH are adjacent to each other.

According to an embodiment, the first opening 620ROP1 in the red color filter 620R above the emission area EA1′ of the green first pixel P1g′ may be apart from the third opening 620ROP3 in the red color filter 620R, the third opening 620BOP3 in the blue color filter 620B, and the third opening 620GOP3 in the green color filter 620G above hole area PH that is adjacent to the green first pixel P1g′.

A portion of the blue color filter 620B arranged between the first opening 620BOP1 in the blue color filter 620B above the emission area EA1′ of the green first pixel P1g′ and the third opening 620BOP3inf the blue color filter 620B above the hole area PH may be covered by at least one of the red color filter 620R and the green color filter 620G. That is, the portion of the blue color filter 620B arranged between the first opening 620BOP1 in the blue color filter 620B above the emission area EA1′ of the green first pixel P1g′ and the third opening 620BOP3 in the blue color filter 620B above the hole area PH may overlap the red color filter 620R and/or the green color filter 620G. An upper surface of the portion of the blue color filter 620B may not be without another color filter. The portion of the blue color filter 620B may overlap the bank layer 123. The portion of the blue color filter 620B may overlap at least one of the red color filter 620R and the green color filter 620G and may block light.

However, referring to FIGS. 18 and 19 again, according to an embodiment, the arrangement of the first pixels P1′ in the first sub-area SA1 may be different from the arrangement of the first pixels P1 in the second sub-area SA2. For example, the first pixels P1′ of the first sub-area SA1 may have the same oval shape as the first pixels P1 of the second sub-area SA2. However, unlike the first pixels P1 in the second sub-area SA2, the first pixels P1′ of the first sub-area SA1 may have their axes oriented in the same direction. This way, few or none of the color filters 620 of the reflection preventive layer 600 around the hole area PH arranged at a boundary area of the first display area DA1 and the first sub-area SA1 would not be covered by another color filter. Thus, the reliability of the display panel may be improved.

According to the one or more embodiments described above, there may be provided a display panel which may have improved reliability and secured transmittance in an area in which components are arranged, and an electronic device including the display panel. However, the scope of the disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A display panel comprising:
a first display area having first light-emitting diodes and first pixel circuits connected to the first light-emitting diodes;
a second display area having second light-emitting diodes and second pixel circuits connected to the second light-emitting diodes, the second display area being at least partially surrounded by the first display area;
a bank layer in the first display area and the second display area, the bank layer comprising first bank openings defining first emission areas of the first light-emitting diodes, second bank openings defining second emission areas of the second light-emitting diodes, and third bank openings defining hole areas between the second emission areas; and
a reflection preventive layer on the first light-emitting diodes and the second light-emitting diodes and comprising color filters having openings above the hole areas,
wherein the first display area comprises a first sub-area in contact with the second display area and a second sub-area outside the first sub-area, and
the first emission areas of the first sub-area differ from the first emission areas of the second sub-area with respect to at least one of shape and arrangement.

2. The display panel of claim 1, wherein at least some of the first emission areas of the first sub-area are adjacent to at least some of the hole areas of the second display area.

3. The display panel of claim 1 wherein, in a plan view, the first emission areas of the first sub-area have a same shape as the second emission areas of the second display area.

4. The display panel of claim 3 wherein, in a plan view, the first emission areas of the second sub-area have oval shapes, and
the second emission areas of the second display area and the first emission areas of the first sub-area have circular shapes.

5. The display panel of claim 1, wherein in a plan view, the second emission areas of the second display area have circular shapes, and
the first emission areas of the first display area have oval shapes.

6. The display panel of claim 5 wherein, in a plan view, the hole areas have oval shapes.

7. The display panel of claim 5 wherein, in a plan view, major axes of the first emission areas of the first sub-area are oriented in a same direction, and
the first emission areas of the second sub-area comprise a first-axis emission area and a second-axis emission area having major axes that are oriented in different directions.

8. The display panel of claim 5 wherein, in a plan view, at least some of the first emission areas of the first sub-area are adjacent, in a first direction, to at least some of the hole areas of the second display area, and
major axes of the first emission areas of the first sub-area extend in a second direction perpendicular to the first direction.

9. The display panel of claim 1, wherein the color filters of the reflection preventive layer comprise a first color filter transmitting first-color light, a second color filter transmitting second-color light, and a third color filter transmitting third-color light, and
the first color filter, the second color filter, and the third color filter define a light-blocking portion by overlapping one another.

10. The display panel of claim 9, wherein the first color filter, the second color filter, and the third color filter are sequentially arranged, and
the first color filter, the second color filter, and the third color filter respectively comprise first openings above the first emission areas, second openings above the second emission areas, and third openings above the hole areas.

11. The display panel of claim 10, wherein a portion of the first color filter arranged between a first opening of the first openings and a third opening of the third openings in the first color filter is covered by at least one of the second color filter and the third color filter.

12. An electronic device comprising:
a display panel; and
a cover coupled to the display panel and having an opening exposing a portion of the display panel,
wherein the display panel comprises:
a first display area having first light-emitting diodes and first pixel circuits connected to the first light-emitting diodes;
a second display area having second light-emitting diodes and second pixel circuits connected to the second light-emitting diodes, the second display area being at least partially surrounded by the first display area;
a bank layer in the first display area and the second display area, the bank layer comprising first bank openings defining first emission areas of the first light-emitting diodes, respectively, second bank openings defining second emission areas of the second light-emitting diodes, respectively, and third bank openings defining hole areas between the second emission areas; and
a reflection preventive layer on the first light-emitting diodes and the second light-emitting diodes and comprising color filters having openings above the hole areas,
wherein the first display area comprises a first sub-area in contact with the second display area and a second sub-area outside the first sub-area, and
the first emission areas of the first sub-area differ from the first emission areas of the second sub-area with respect to at least one of shape and arrangement.

13. The electronic device of claim 12, wherein at least some of the first emission areas of the first sub-area are adjacent to at least some of the hole areas of the second display area.

14. The electronic device of claim 12 wherein, in a plan view, the first emission areas of the first sub-area have a same shape as the second emission areas of the second display area.

15. The electronic device of claim 14, wherein, in a plan view, the first emission areas of the second sub-area have oval shapes, and
the second emission areas of the second display area and the first emission areas of the first sub-area have circular shapes.

16. The electronic device of claim 12 wherein, in a plan view, the second emission areas of the second display area have circular shapes, and
the first emission areas of the first display area have oval shapes.

17. The electronic device of claim 16 wherein, in a plan view, major axes of the first emission areas of the first sub-area are oriented in a same direction, and
the first emission areas of the second sub-area comprise a first-axis emission area and a second-axis emission area having major axes that are oriented in different directions.

18. The electronic device of claim 16 wherein, in a plan view, at least some of the first emission areas of the first sub-area are adjacent, in a first direction, to at least some of the hole areas of the second display area, and
major axes of the first emission areas of the first sub-area extend in a second direction perpendicular to the first direction.

19. The electronic device of claim 12, wherein the color filters of the reflection preventive layer comprise a first color filter transmitting first-color light, a second color filter transmitting second-color light, and a third color filter transmitting third-color light, and
the first color filter, the second color filter, and the third color filter define a light-blocking portion by overlapping one another.

20. The electronic device of claim 12, further comprising a component arranged between the display panel and the cover,
wherein the component aligns with the hole area.
